(19) United States
(12) Patent Application Publication
(10) Pub. No.: US 2026/0009870 A1
(43) Pub. Date: Jan. 8, 2026

(54) TUNNEL MAGNETORESISTANCE ELEMENT, MAGNETIC SENSOR MODULE, AND CURRENT SENSOR

(71) Applicant: Asahi Kasei Microdevices Corporation, Tokyo (JP)

(72) Inventor: Masato INOUE, Tokyo (JP)

(21) Appl. No.: 19/224,931

(22) Filed: Jun. 2, 2025

(30) Foreign Application Priority Data
Jul. 3, 2024 (JP) 2024-107174
Apr. 11, 2025 (JP) 2025-065880

(51) Int. Cl. G01R 33/09; G01R 15/20

(52) U.S. Cl. CPC G01R 33/098; G01R 15/205

(57) ABSTRACT

A TMR element 51 includes a fixed layer 510, an insulating layer 51p, and a free layer 51q which are sequentially stacked in a z axis direction, the free layer 51q has a column shape extending in the z axis direction and spreading in a horizontal direction, and with a height t of the free layer 51q in the z axis direction and an effective size d of the free layer 51q with respect to spread in the horizontal direction, an aspect ratio (t/d) given by using the height (film thickness) t and the effective size d is 1 or more, the height t is 20 nm or more, and the effective size d is 2.57×10⁻² (A)/Ms or less, with a saturation magnetization Ms (A/nm) of the free layer.

The contents of the following patent application(s) are incorporated herein by reference:
NO. 2024-107174 filed in JP on Jul. 3, 2024
NO. 2025-065880 filed in JP on Apr. 11, 2025.

### BACKGROUND

### 1. Technical Field

The present invention relates to a tunnel magnetoresistance element, a magnetic sensor module, and a current sensor.

### 2. Related Art

For example, in a drive system of an electric vehicle, a current of 300 A is supplied to a load during peak operation, and thus a current sensor capable of detecting a large current is required. When a coreless current sensor including a tunnel magnetoresistance element (TMR element) is used, an electromagnetic conversion coefficient is 0.2 to 0.6 mT/A, and thus a wide-range TMR element with high sensitivity is required which can be used in a measurement range of an external magnetic field (referred to as a magnetic field range) of 50 to 200 mT. However, in the TMR element, it is generally difficult to achieve both a wide magnetic field range and high sensitivity (see, for example, Patent Document 1).
Patent Document 1: International Publication No. 2021/001738

### GENERAL DISCLOSURE

According to a first aspect of the present invention, there is provided a tunnel magnetoresistance element including a fixed layer, an insulating layer, and a free layer which are sequentially stacked in a uniaxial direction, in which the free layer has a column shape extending in the uniaxial direction and spreading in a planar direction intersecting the uniaxial direction, and with a height t of the free layer in the uniaxial direction and an effective size d of the free layer with respect to spread in the planar direction, an aspect ratio given by using the height t/the effective size d is 1 or more, the height t is 20 nm or more, and the effective size d is 2.57×10⁻² (A)/Ms or less, with a saturation magnetization Ms (A/nm) of the free layer.

According to a second aspect of the present invention, there is provided a tunnel magnetoresistance element including a fixed layer, an insulating layer, and a free layer which are sequentially stacked in a uniaxial direction, in which the free layer has a column shape extending in the uniaxial direction and spreading in a planar direction intersecting the uniaxial direction, and a magnetic moment within the free layer is oriented in the uniaxial direction or oriented in a direction inclined circumferentially about a central axis of the column shape with respect to the uniaxial direction.

In a third aspect of the present invention, there is provided a magnetic sensor module in which at least two tunnel magnetoresistance elements of the first or second aspect are arranged on a same plane and connected in parallel between two electrodes.

According to a fourth aspect of the present invention, there is provided a current sensor including the magnetic sensor module of the third aspect arranged on a U-shaped or substantially U-shaped bus bar, in which a plurality of tunnel magnetoresistance elements including the tunnel magnetoresistance element are periodically arrayed in a third direction on the same plane and a fourth direction intersecting the third direction, an array pitch of the tunnel magnetoresistance elements in the third direction is larger than an array pitch in the fourth direction, and the third direction is parallel to a direction of a current flowing through the bus bar.

The summary clause does not necessarily describe all necessary features of the embodiments of the present invention. The present invention may also be a sub-combination of the features described above.

### BRIEF DESCRIPTION OF THE DRAWINGS

FIG. 1A illustrates an internal configuration of a current sensor according to the present embodiment in top view.

FIG. 1B illustrates the internal configuration of the current sensor according to the present embodiment in side view.

FIG. 2A illustrates an example of arrangement and a substrate layout of a magnetic sensor module which detects a horizontal magnetic field.

FIG. 2B illustrates a configuration of a TMR element in side view.

FIG. 3 illustrates a circuit configuration of the magnetic sensor module (first and second magnetoelectric conversion units) and a magnetic field detection direction of a magnetoresistance element.

FIG. 4A illustrates an internal configuration and design parameters of the TMR element (free layer, insulating layer, and fixed layer).

FIG. 4B illustrates a distribution of magnetic moments in the TMR element having perpendicular magnetization.

FIG. 4C illustrates a distribution of magnetic moments in the TMR element having vortex magnetization.

FIG. 4D illustrates a distribution of magnetic moments in the TMR element having tornado magnetization.

FIG. 5A illustrates ideal magnetization characteristics of the TMR element (circular cross section).

FIG. 5B illustrates magnetization dynamics in the TMR element having perpendicular magnetization.

FIG. 6A illustrates a design map (an example of saturation magnetization of 0.25 T) of an ideal-characteristic TMR element (circular cross section).

FIG. 6B illustrates a design map (an example of saturation magnetization of 0.35 T) of the ideal-characteristic TMR element (circular cross section).

FIG. 6C illustrates a design map (an example of saturation magnetization of 0.45 T) of the ideal-characteristic TMR element (circular cross section).

FIG. 6D illustrates a design map (an example of saturation magnetization of 0.55 T) of the ideal-characteristic TMR element (circular cross section).

FIG. 6E illustrates a design map (an example of saturation magnetization of 0.65 T) of the ideal-characteristic TMR element (circular cross section).

FIG. 6F illustrates a design map (an example of saturation magnetization of 0.75 T) of the ideal-characteristic TMR element (circular cross section).

FIG. 7 illustrates magnetization characteristics of the TMR element having a polygonal cross section.

FIG. 8A illustrates a design map (an example of saturation magnetization of 0.25 T) of the ideal-characteristic TMR element (square cross section).

FIG. 8B illustrates a design map (an example of saturation magnetization of 0.35 T) of the ideal-characteristic TMR element (square cross section).

FIG. 8C illustrates a design map (an example of saturation magnetization of 0.45 T) of the ideal-characteristic TMR element (square cross section).

FIG. 8D illustrates a design map (an example of saturation magnetization of 0.65 T) of the ideal-characteristic TMR element (square cross section).

FIG. 9A illustrates a configuration example of a single-row module of the TMR element.

FIG. 9B illustrates a configuration example of a parallel module of the TMR element.

FIG. 10A illustrates filling rate dependency of magnetization characteristics of a TMR module (the TMR element has a circular cross section).

FIG. 10B illustrates the filling rate dependency of the magnetization characteristics of the TMR module (the TMR element has a square cross section).

FIG. 11A illustrates an example of a cross-sectional shape and array of the TMR elements constituting the TMR module (an example of a single shape).

FIG. 11B illustrates an example of the cross-sectional shape and the array of the TMR elements constituting the TMR module (an example of a single shape).

FIG. 11C illustrates an example of the cross-sectional shape and the array of the TMR elements constituting the TMR module (an example of a single shape).

FIG. 11D illustrates an example of the cross-sectional shape and the array of the TMR elements constituting the TMR module (an example of a single shape).

FIG. 12A illustrates an example of the cross-sectional shape and the array of the TMR elements constituting the TMR module (an example of multiple shapes).

FIG. 12B illustrates an example of the cross-sectional shape and the array of the TMR elements constituting the TMR module (an example of multiple shapes).

FIG. 12C illustrates an example of the cross-sectional shape and the array of the TMR elements constituting the TMR module (an example of multiple shapes).

FIG. 13 illustrates sensitivity selectivity of the TMR module.

FIG. 14A illustrates arrangement of the TMR elements which are hardly affected by a magnetic field in a perpendicular direction.

FIG. 14B illustrates arrangement of the TMR elements which are hardly affected by the perpendicular magnetic field in the perpendicular direction.

FIG. 15A illustrates an example of arrangement and a substrate layout of a full-bridge type magnetic sensor which detects the horizontal magnetic field.

FIG. 15B illustrates a circuit configuration of the full-bridge type magnetic sensor (two magnetoelectric conversion units) and the magnetic field detection direction of the magnetoresistance element.

FIG. 15C illustrates a change in magnetoresistance of magnetoresistance elements within first and second blocks and the entire sensor with respect to an energization amount of a bus bar.

FIG. 16A illustrates a state of a lead frame forming step in a manufacturing flow of the current sensor.

FIG. 16B illustrates a state of a magnetic sensor module installation step in the manufacturing flow of the current sensor.

FIG. 16C illustrates a state of a wire bonding step in the manufacturing flow of the current sensor.

FIG. 16D illustrates a state of a molding step in the manufacturing flow of the current sensor.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention.

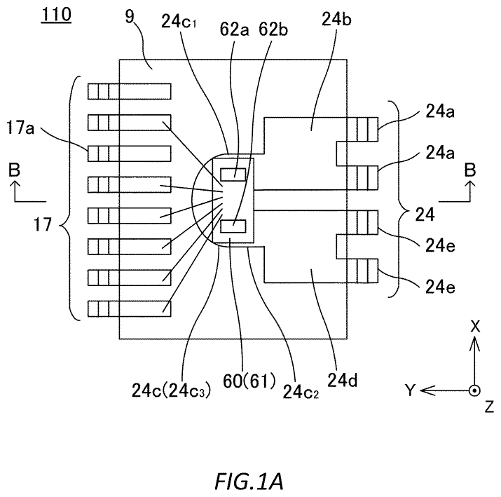

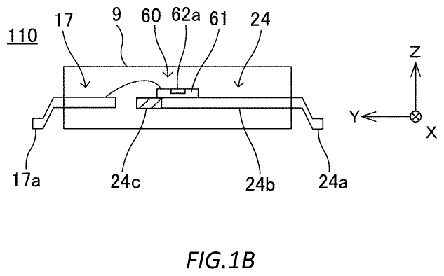

In FIGS. 1A and 1B, an internal configuration of a current sensor 110 according to the present embodiment is illustrated through a package 9 in top view and side view, respectively. Here, FIG. 1B illustrates a cross-sectional structure of the current sensor 110 with respect to a reference line BB in FIG. 1A. Note that an up-down direction in FIG. 1A is a longitudinal direction (also referred to as an X axis direction), a right-left direction in FIGS. 1A and 1B is a lateral direction (also referred to as a Y axis direction), and an up-down direction in FIG. 1B is a height direction (also referred to as a Z axis direction). The current sensor 110 is a sensor which measures an amount of current by detecting a magnetic field, which is generated around a current to be measured when the current to be measured flows through a bus bar 24, with a magnetic sensor module 60 formed using a TMR element 51, and includes the package 9, a plurality of device terminals 17, the bus bar 24, and the magnetic sensor module 60.

The package 9 is a member which seals each component of the current sensor 110 inside it to protect the component, except for respective terminal portions of the plurality of device terminals 17 and the bus bar 24. The package 9 is molded into a flat rectangular body, for example, by using a sealing resin with an excellent insulation property such as epoxy.

Each of the plurality of device terminals 17 is connected to an electrode pad (not illustrated) of the magnetic sensor module 60, and is a secondary conductor for outputting, to an external device, a detection result of the current to be measured (that is, magnetic field intensity) output from the magnetic sensor module 60. In the present example, as an example, eight device terminals 17 are arrayed at equal intervals with their longitudinal sides directed in the lateral direction on a left side of the package 9. The device terminals 17 are molded in a rectangular plate shape by using metal, their end portions are bent downward by bending, and further their distal ends are bent horizontally, whereby terminal portions 17a are formed at their end portions, respectively.

The bus bar 24 is a primary conductor which forms a current path through which the current to be measured flows. In the present embodiment, the bus bar 24 is a U-shaped or substantially U-shaped conductor which returns from a current terminal 24a provided on one side (that is, an upper side in FIG. 1A) of a right side of the package 9 to the right side through an inside of the package 9 and reaches a current terminal 24e provided on another side (that is, a lower side in FIG. 1A) of the right side. The bus bar 24 is molded by using a conductive metal. The bus bar 24 includes the current terminals (also simply referred to as terminal portions) 24a and 24e, body portions 24b and 24d, and a curved portion 24c.

The terminal portions 24a and 24e protrude from the right side of the package 9, their end portions are bent downward by bending, and further their distal ends are bent horizontally, thereby forming terminals for inputting a current.

The body portions 24b and 24d are parts which connect the terminal portions 24a and 24e to the curved portion 24c. The body portions 24b and 24d are formed in a rectangular shape as an example, on their right side, two terminal portions 24a and two terminal portions 24e are connected at a distance from each other, respectively, and on their left side, two arms 24c₁ and 24c₂ of the curved portion 24c are connected.

The curved portion 24c includes two arms 2401 and 24c₂ and a linking portion 24c₃ which links these two arms 2401 and 24c₂. Here, a direction in which a width of the arm 24c₁ increases is also referred to as a width direction (equal to the longitudinal direction in FIG. 1A). The two arms 24c₁ and 24c₂ have smaller widths in the longitudinal direction than those of the body portions 24b and 24d. In the curved portion 24c, the linking portion 24c₃ is bent in a substantially arc shape, and from both ends thereof, the two arms 24c₁ and 24c₂ extends in the lateral direction and are separated from each other in the width direction. Note that the curved portion 24c may be bent in a U shape. In the curved portion 24c, the current to be measured is input to one arm of the two arms 24c₁ and 24c₂, and the current to be measured is output from another arm via the linking portion 24c₃.

In the bus bar 24, the two arms 24c₁ and 24c₂ included in the curved portion 24c are arranged at a center of the package 9, and the distal ends of the terminal portions 24a and 24e protrude from the right side of the package 9 and are sealed in the package 9.

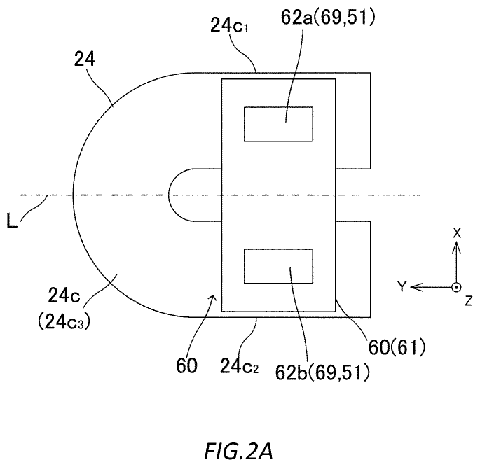

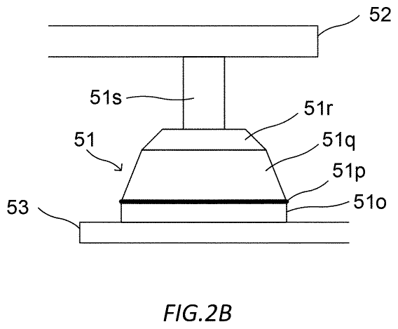

FIG. 2A illustrates an example of arrangement and a substrate layout of the magnetic sensor module (also simply referred to as a magnetic sensor) 60. The magnetic sensor module 60 is a sensor which detects a magnetic field generated by the current to be measured applied to the bus bar 24. The magnetic sensor module 60 is configured to detect, as an example, a longitudinal magnetic field (or a horizontal magnetic field) which is generated on a surface of the bus bar 24 when the current to be measured flows through the bus bar 24, and includes a substrate 61 and a plurality of TMR elements 51.

The substrate 61 is a plate-shaped member which supports two magnetoelectric conversion units 62a and 62b. The substrate 61 is formed by using, for example, silicon (Si), and a plurality of wirings and a plurality of electrode pads (both not illustrated) are formed on an upper surface thereof.

The plurality of TMR elements 51 are disposed on one side and another side in the longitudinal direction on the substrate 61 to form the two magnetoelectric conversion units 62a and 62b, respectively. The magnetoelectric conversion unit 62a is formed by configuring a part (that is, the TMR element 51 disposed on an upper side in FIG. 2A) of the plurality of TMR elements 51 into a Wheatstone bridge circuit shape. The magnetoelectric conversion unit 62b is formed by configuring another part (that is, the TMR element 51 disposed on a lower side in FIG. 2A) of the plurality of TMR elements 51 into a Wheatstone bridge circuit shape.

FIG. 2B illustrates a configuration of the TMR element 51 in side view. The TMR element 51 is an element, a resistance value of which fluctuates due to application of a magnetic field, and includes a fixed layer 510, an insulating layer (also referred to as a tunnel layer) 51p, a free layer 51q, and a cap layer 51r.

The fixed layer 510 is a magnetic film having a fixed magnetization orientation. The fixed layer 510 is magnetized such that magnetization thereof is oriented in a uniaxial direction (horizontal direction) within a plane (also referred to as a magnetism sensing surface) on which the magnetic film spreads or a direction perpendicular to a magnetism sensing surface. In the present example, the fixed layer 510 is magnetized such that the magnetization is oriented in the horizontal direction. A magnetization orientation of the fixed layer 510 determines a magnetic field detection direction of the TMR element 51.

The insulating layer 51p is, for example, a nonmagnetic insulating film having a thickness of several nanometers. The insulating layer 51p may contain at least magnesium oxide (MgO).

The free layer 51q is a magnetic film a magnetization orientation of which changes due to an external magnetic field. Note that a material of the magnetic film is, for example, an alloy containing at least one of cobalt (Co), iron (Fe), boron (B), nickel (Ni), or silicon (Si), and more specifically, cobalt iron (CoFe), cobalt iron boron (CoFeB), and nickel iron (NiFe) can be used. In particular, by using NiₓFe₁₋ₓ (x=0.25 to 0.30) forming a body-centered cubic lattice (Niklas Volbers, Soft Magnetic Crystalline NiFe and CoFe Alloys Status and New Developments, Proc. Of WMM2018), saturation magnetization of the free layer 51q can be made 0.65 T or less.

The cap layer 51r is a member which is stacked on the free layer 51q to cover a stacked body from above, and for example, at least one of tantalum (Ta), ruthenium (Ru), platinum (Pt), manganese (Mn), iridium (Ir), magnesium (Mg), copper (Cu), iron (Fe), nickel (Ni), chromium (Cr), iron (Fe), cobalt (Co), or aluminum (Al) or an alloy thereof, more specifically, platinum manganese (PtMn) or iridium manganese (IrMn) can be used. Note that a periphery of the TMR element 51 is covered with an insulator (not illustrated), for example, silicon dioxide (SiO₂), silicon nitride (SiN), or the like.

Note that the free layer 51q contains cobalt (Co) and/or iron (Fe), and may further contain at least one type of paramagnetic transition metal elements. The paramagnetic transition metal elements may contain at least one or more of Ti, Cr, Mn, Cu, Zn, Mo, Ru, Rh, Pd, Ag, Ta, W, Pt, Au, Ti, or oxides or nitrides thereof. By including these paramagnetic transition metals (also referred to as dilution elements) in ferromagnetic transition metals such as Co, Fe, and Ni, the saturation magnetization of the free layer can be reduced to obtain a desired value. Furthermore, it is also possible to suppress sensitivity temperature fluctuation due to high temperature, which becomes a problem in the current sensor.

The fixed layer 510, the insulating layer 51p, the free layer 51q, and the cap layer 51r are stacked to constitute a multilayer film. As an example, a surface of a substrate such as silicon (Si) (an insulating film such as a Si oxide film may be formed) is etched by plasma treatment, an underlayer (for example, Ta/CuN/Ta/CuN/Ru) and an antiferromagnetic pinning layer (for example, IrMn) are sequentially deposited on the surface, and a ferromagnetic pinned layer (for example, Co₇₀Fe₃₀), a metal spacer (for example, Ru), and a ferromagnetic reference layer (for example, CoFeB) are sequentially deposited thereon. The ferromagnetic pinned layer, the metal spacer, and the ferromagnetic reference layer constitute a SAF structure to form the fixed layer 510. Furthermore, the insulating layer 51p (for example, MgO) is formed thereon, a ferromagnetic layer (for example, CoFeB) is deposited thereon to form the free layer 51q, and the cap layer 51r (for example, Ta, Ru, or the like) is formed thereon. The multilayer film may be patterned and annealed in a magnetic field of 300° C. Accordingly, a TMR element is obtained in which electrons tunnel through the insulating layer 51p and move from the fixed layer 510 to the free layer 51q or from the free layer 51q to the fixed layer 510, so that a current can flow in the element in a stacking direction.

When an external magnetic field is applied to the TMR element 51, due to a magnetoresistance effect (MR effect), the magnetization orientation of the free layer 51q changes according to an orientation and intensity of the magnetic field, that is, the magnetization orientation of the free layer 51q changes with respect to the magnetization orientation of the fixed layer 510, whereby the resistance value between the fixed layer 510 and the free layer 51q fluctuates. In particular, when the magnetization orientation of the free layer 51q is the same as the magnetization orientation of the fixed layer 510 (the magnetizations of the two layers is parallel), the resistance value becomes small, and when the magnetization orientations of the two layers are opposite to each other (the magnetizations of the two layers is antiparallel), the resistance value becomes large.

Note that a DC withstand voltage can be improved by connecting the plurality of TMR elements 51 in series. Here, by connecting an electrode piece 52 to the cap layer 51r via an electrode rod 51s and connecting an electrode piece 53 to a lower surface of the fixed layer 510, the TMR element 51 can be connected to another TMR element 51 via these electrode pieces 52 and 53. That is, the plurality of TMR elements 51 can be arrayed in a planar configuration. In addition, by connecting the cap layer 51r of the TMR element 51 to the fixed layer 510 of another TMR element 51 via the electrode rod 51s, the plurality of TMR elements 51 can be arrayed in a three-dimensional configuration.

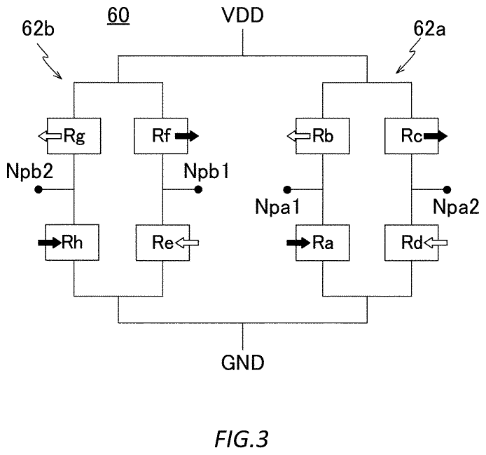

FIG. 3 illustrates a circuit configuration of the magnetic sensor module 60 (two magnetoelectric conversion units 62a and 62b) and a magnetic field detection direction of (the TMR element 51 included in each of) resistive arms Ra to Rh. The magnetic sensor module 60 includes the two magnetoelectric conversion units 62a and 62b connected in parallel between their respective drive terminal VDD and ground terminal GND.

The magnetoelectric conversion unit 62a includes four resistive arms Ra to Rd forming a Wheatstone bridge circuit. Each of the resistive arms Ra to Rd is formed by connecting the above-described plurality of TMR elements 51 in series. Note that the plurality of TMR elements 51 may also be connected in parallel, or may also be connected in series and in parallel. Herein, in the four resistive arms Ra to Rd, the resistive arm Ra and the resistive arm Rb are connected in series to form an output terminal Npa1 therebetween, the resistive arm Rc and the resistive arm Rd are connected in series to form an output terminal Npa2 therebetween, and the resistive arm Ra and the resistive arm Rb, and the resistive arm Rc and the resistive arm Rd are connected in parallel to form the drive terminal VDD between the resistive arm Rb and the resistive arm Rc and form the ground terminal GND between the resistive arm Ra and the resistive arm Rd.

Note that in the current sensor 110 according to the present embodiment, the magnetic field detection direction (that is, a magnetic sensing direction) from the resistive arm Ra to the resistive arm Rd is a uniaxial direction (the longitudinal direction in FIG. 1A) parallel to the upper surface of the bus bar 24. The magnetic field detection directions of (the TMR elements 51 respectively forming) the resistive arm Ra and the resistive arm Rc are equal to each other (indicated by black arrows in FIG. 3), and, in the present example, are upward (or downward) in the longitudinal direction in FIG. 1A. The magnetic field detection directions of (the TMR elements 51 respectively forming) the resistive arm Rb and the resistive arm Rd are also equal to each other (indicated by white arrows in FIG. 3), and, in the present example, are downward (or upward) in the longitudinal direction in FIG. 1A. The magnetic field detection directions of the resistive arm Ra and the resistive arm Rc are opposite to the magnetic field detection directions of the resistive arm Rb and the resistive arm Rd.

The magnetoelectric conversion unit 62a is arranged on the arm 24c₁ of the bus bar 24. When a current to be measured flows through the bus bar 24 and a magnetic field is generated around the bus bar 24, a longitudinal magnetic field is applied to (the TMR elements 51 included in) the resistive arms Ra to Rd of the magnetoelectric conversion unit 62a arranged on the arm 24c₁ of the bus bar 24, and each resistance value thereof fluctuates. For example, the resistance values of the resistive arms Ra and Rc increase (or decrease), and the resistance values of the resistive arms Rb and Rd decrease (or increase), thereby breaking a resistance balance of the resistive arms Ra to Rd. Here, magnetic field intensity can be detected by inputting a drive voltage to the drive terminal VDD with respect to the ground terminal GND and detecting a differential voltage output from between the output terminals Npa1 and Npa2. As a result, the horizontal magnetic field generated on the upper surface of the arm 24c₁ can be detected.

The magnetoelectric conversion unit 62b is configured similarly to the magnetoelectric conversion unit 62a, and includes four resistive arms Re to Rh constituting a Wheatstone bridge circuit. Each of the resistive arms Re to Rh is formed by connecting the above-described plurality of TMR elements 51 in series. Note that the plurality of TMR elements 51 may also be connected in parallel, or may also be connected in series and in parallel. Herein, in the four resistive arms Re to Rh, the resistive arm Re and the resistive arm Rf are connected in series to form an output terminal Npb1 therebetween, the resistive arm Rg and the resistive arm Rh are connected in series to form an output terminal Npb2 therebetween, and the resistive arm Re and the resistive arm Rf, and the resistive arm Rg and the resistive arm Rh are connected in parallel to form the drive terminal VDD between the resistive arm Rf and the resistive arm Rg and form the ground terminal GND between the resistive arm Re and the resistive arm Rh.

Note that in the current sensor 110 according to the present embodiment, the magnetic field detection direction (that is, the magnetic sensing direction) from the resistive arm Re to the resistive arm Rh is a uniaxial direction (the longitudinal direction in FIG. 1A) parallel to the upper surface of the bus bar 24, similarly to that from the resistive arm Ra to the resistive arm Rd. The magnetic field detection directions of (the TMR elements 51 respectively forming) the resistive arm Re and the resistive arm Rg are equal to each other (indicated by white arrows in FIG. 3), and in the present example, are upward (or downward) in the longitudinal direction in FIG. 1A. The magnetic field detection directions of (the TMR elements 51 respectively forming) the resistive arm Rf and the resistive arm Rh are also equal to each other (indicated by black arrows in FIG. 3), and in the present example, are downward (or upward) in the longitudinal direction in FIG. 1A. The magnetic field detection directions of the resistive arm Re and the resistive arm Rg are opposite to the magnetic field detection directions of the resistive arm Rf and the resistive arm Rh.

The magnetoelectric conversion unit 62b is arranged on the arm 24c₂ of the bus bar 24. When a current to be measured flows through the bus bar 24 and a magnetic field is generated around the bus bar 24, a longitudinal magnetic field is applied to (the TMR element 51 included in) the resistive arms Re to Rh of the magnetoelectric conversion unit 62b arranged on the arm 24c₂ of the bus bar 24, and each resistance value thereof fluctuates. For example, the resistance values of the resistive arms Re and Rg increase (or decrease), and the resistance values of the resistive arms Rf and Rh decrease (or increase), thereby breaking a resistance balance of the resistive arms Re to Rh. Here, magnetic field intensity can be detected by inputting a drive voltage to the drive terminal VDD with respect to the ground terminal GND and detecting a differential voltage output from between the output terminals Npb1 and Npb2. As a result, the horizontal magnetic field generated on the upper surface of the arm 24c₂ can be detected.

Note that as described above, the two magnetoelectric conversion units 62a and 62b can be arranged on two arms 24c₁ and 24c₂ of the bus bar 24, respectively. As a result, a disturbance magnetic field can be canceled. Note that only one of the two magnetoelectric conversion units 62a and 62b may be arranged on the bus bar 24 (the two arms 24c₁ and 24c₂, the linking portion 24c₃, or the like).

The two magnetoelectric conversion units 62a and 62b are arranged on one side and another side on the substrate 61 separately in the longitudinal direction (the width direction of the arms 24c₁ and 24c₂), respectively, and the drive terminal VDD, the ground terminal GND, and the output terminals Npa1, Npa2, Npb1, and Npb2 thereof are connected to electrode pads (not illustrated) on the substrate 61, whereby, via these connections, a drive voltage can be input from an outside to a power supply terminal, and a differential voltage can be output from the output terminal to the outside.

The magnetic sensor module 60 is arranged on the curved portion 24c of the bus bar 24. Accordingly, the two magnetoelectric conversion units 62a and 62b are arranged on the two arms 24c₁ and 24c₂ of the curved portion 24c, respectively, and the drive terminal VDD, the ground terminal GND, and the output terminals Npa1, Npa2, Npb1, and Npb2 of the two magnetoelectric conversion units 62a and 62b are connected to the device terminal 17 via a plurality of electrode pads (not illustrated) on the substrate 61 by wire bonding. Accordingly, it is possible to apply a drive voltage to the two magnetoelectric conversion units 62a and 62b via the device terminal 17 and to output each differential voltage thereof.

Note that the magnetic sensor module 60 includes the two magnetoelectric conversion units 62a and 62b, but may include only one of them instead. In addition, in FIG. 3, the magnetoelectric conversion units 62a and 62b may not be connected in parallel and each may be configured as an independent circuit. That is, the magnetic sensor module 60 may be constituted by each of the magnetoelectric conversion units 62a and 62b or only one of them. Each of the magnetoelectric conversion units 62a and 62b may be referred to as the magnetic sensor module 60.

Note that another of the two magnetoelectric conversion units 62a and 62b may be arranged near an outer side of one of the two arms 24c₁ and 24c₂ of the bus bar 24. Accordingly, the disturbance magnetic field can be canceled.

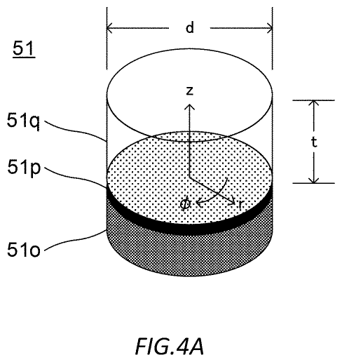

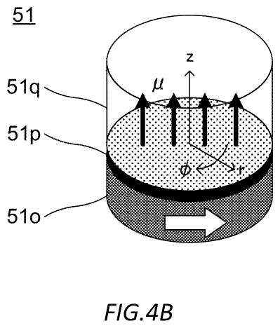

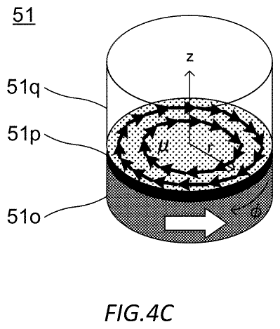

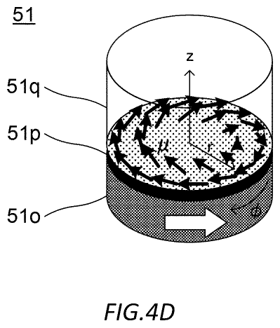

FIG. 4A illustrates an internal configuration and design parameters of the TMR element 51.

As described above, the TMR element 51 includes the fixed layer 510 in which a magnetic moment does not rotate (the magnetization does not change) and remains oriented in a planar direction intersecting a z axis direction when the external magnetic field is applied, the insulating layer (also referred to as a tunnel layer) 51p, and the free layer 51q in which the magnetic moment rotates (the magnetization changes) when the external magnetic field is applied, which are sequentially stacked in the uniaxial direction (referred to as the z axis direction). Here, at least the free layer 51q has a column shape extending in the z axis direction and spreading in the planar direction (also referred to as a radial direction (r direction) or a horizontal direction with respect to the z axis direction) intersecting the z axis direction. A central axis of the column shape coincides with a z axis. A height (or a film thickness) of the free layer 51q in the z axis direction is denoted as t, and an effective size of the free layer 51q with respect to spread in the horizontal direction is denoted as d. The effective size d can be given as, for example, by using a cross-sectional area S of the free layer 51q as viewed in the z axis direction and a circular constant π, d=2√(S/π). When the free layer 51q has a circular cross section, the effective size d is equal to its diameter.

FIG. 4B illustrates a distribution of magnetic moments in the TMR element having perpendicular magnetization (referred to as a perpendicular magnetization type TMR element). In the perpendicular magnetization type TMR element based on interface perpendicular magnetic anisotropy (see, for example, U.S. Patent Application Publication No. 2021/080520), a bonding orbital exhibiting interface perpendicular magnetic anisotropy is formed on an interface between the tunnel layer 51p and the free layer 51q, so that a magnetic moment u is oriented in a direction perpendicular to the interface (z axis direction), and a perpendicular magnetic moment at the interface propagates throughout an interior of the free layer 51q by exchange interaction, whereby, in absence of the magnetic field, the magnetic moment within the free layer 51q is stabilized with its orientation in the perpendicular direction. Accordingly, it becomes difficult to rotate (that is, magnetize) the magnetic moment u with respect to the external magnetic field in a direction parallel to the interface, and linearity is improved. However, the perpendicular magnetization type TMR element becomes nonlinear due to a high-order component of anisotropy energy related to the interface perpendicular magnetic anisotropy (T. Ogasahara et al., Scientific Reports 9, 17018 (2019)). Therefore, in the perpendicular magnetization type TMR element, when the magnetic field range is set within a range of an allowable nonlinearity error, the sensitivity decreases, and conversely, when high sensitivity is maintained, the magnetic field range becomes narrow.

FIGS. 4C and 4D illustrate magnetic moment distributions in a TMR element having vortex magnetization (vortex magnetization type TMR element) and a TMR element having tornado magnetization (tornado magnetization type TMR element), respectively. In the vortex magnetization type TMR element (for example, European Patent Application Publication No. 3992655), the magnetic moment u within the free layer 51q is oriented in a circumferential direction (o direction) with respect to the stacking direction (z axis direction) in which the fixed layer, the insulating layer, and the free layer 51q are stacked, to form a vortex structure, so that the magnetic moment particularly on the side surface of the free layer 51q is terminated (for example, forms a closed loop) and stabilized. In the tornado magnetization type TMR element, the magnetic moment u within the free layer 51q is oriented in a direction inclined circumferentially (¢ direction) about the central axis (z axis) of the column shape with respect to the z axis direction on the interface between the tunnel layer 51p and the free layer 51q, and this propagates in the z axis direction in the free layer 51q to form a tornado structure, so that the magnetic moment particularly on the side surface of the free layer 51q is terminated and stabilized. Accordingly, it becomes difficult to rotate (that is, magnetize) the magnetic moment with respect to the external magnetic field in the direction parallel to the interface, and linearity is improved. However, the vortex magnetization type TMR element becomes nonlinear since its magnetization characteristics involve exchange interaction, demagnetizing field energy, and magnetostatic energy, and further becomes nonlinear as magnetic saturation progresses discontinuously due to vortex collapse when an external magnetic field of at least a certain level is applied (N. Strelkov et al., IEEE Trans. Magn. 59, 7100105 (2023)). Therefore, in the vortex magnetization type TMR element, the sensitivity decreases when the magnetic field range is set within a range of an allowable nonlinearity error without vortex collapse.

In the present embodiment, the TMR element 51 having high sensitivity in a wide magnetic field range is designed by improving trade-off between the magnetic field range and the sensitivity by using shape magnetic anisotropy. For this purpose, the magnetic moment distribution within the free layer 51q was analyzed by micromagnetic simulation, and based on this, the magnetization characteristic and the magnetic field range with respect to the external magnetic field applied to the free layer 51q were analyzed. Here, the micromagnetic simulation is a simulation method in which a magnetic body is divided into minute parts (magnetic domains) from microns to nanoscale to calculate magnetization vectors of the respective magnetic domains, and the entire magnetization vector distribution is numerically calculated in consideration of various interactions such as spin interactions and an influence of an external magnetic field by a finite element method (FEM), a finite difference method (FDM), or the like.

Since the TMR element 51 according to the present embodiment is small enough that no domain walls are generated in the free layer 51q, a free layer of a single magnetic domain is assumed. In the simulation, a shape and a size of the free layer 51q, saturation magnetization, and external magnetic field intensity were given, and in consideration of exchange mutual energy (exchange stiffness constant=1.3×10⁻²⁰ J/nm), demagnetizing field energy, and magnetostatic energy generated by the external magnetic field, the magnetic moment distribution within the free layer 51q was decided such that a total energy was minimized (most stabilized) with respect to the given external magnetic field. The obtained magnetic moment distribution was averaged inside the free layer 51q to obtain magnetization (that is, a magnetic field direction component of the magnetic moment), a magnetic susceptibility (which is a normalized magnetic susceptibility given by dividing the magnetization by the saturation magnetization, and a fluctuation with respect to the intensity of the external magnetic field is referred to as a magnetization characteristic) with respect to the external magnetic field was decided, a nonlinearity error in the external magnetic field was calculated from this magnetization characteristic, and a maximum value of the external magnetic field at which the nonlinearity error was 1% or less was defined as the magnetic field range. Note that the nonlinearity error can be given as, for example, an error from linearity when the magnetization characteristic is linearly approximated by a least squares method.

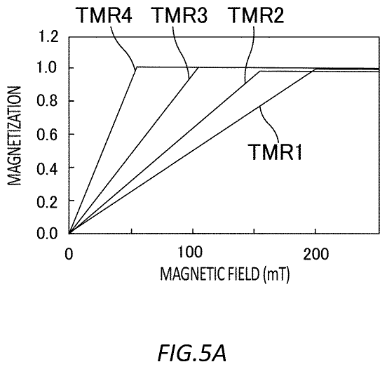

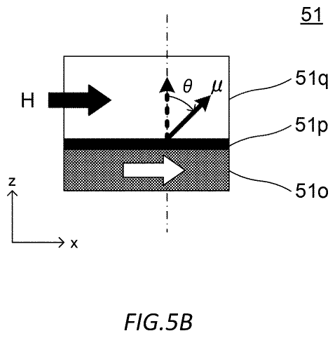

FIG. 5A illustrates results of the magnetization characteristics of the TMR elements obtained by the micromagnetic simulation. Here, the free layer 51q was assumed to have a cylindrical shape with a circular cross section. In addition, with a vacuum permeability μ₀, a saturation magnetization Ms of the free layer, a diameter (effective size) d, and a film thickness (height) t, the values were set as follows: (TMR1) μ₀Ms=0.65 T, d=20 nm, t=60 nm; (TMR2) μ₀Ms=0.65 T, d=30 nm, t=60 nm; (TMR3) μ₀Ms=0.45 T, d=40 nm, t=80 nm; and (TMR4) μ₀Ms=0.35 T, d=40 nm, and t=60 nm. The magnetization characteristic increases almost linearly as the intensity of the external magnetic field increases, and is saturated (magnetic saturation) to a constant value when the intensity of the external magnetic field exceeds a given saturation magnetic field. Here, in the magnetization characteristic of (TMR1), the nonlinearity error is 1% or less until the magnetic field range is 200 mT, and at the magnetic field of 200 mT, the magnetization becomes 0.99, substantially reaching magnetic saturation. In the magnetization characteristic of (TMR2), the nonlinearity error is 1% or less until the magnetic field range is 150 mT, and at the magnetic field of 150 mT, the magnetization becomes 0.95, substantially reaching magnetic saturation. In the magnetization characteristic of (TMR3), the nonlinearity error is 1% or less until the magnetic field range is 100 mT, and at the magnetic field of 100 mT, the magnetization becomes 0.96, substantially reaching magnetic saturation. In the magnetization characteristic of (TMR4), the nonlinearity error is 1% or less until the magnetic field range is 50 mT, and at the magnetic field of 50 mT, the magnetization becomes 0.92, substantially reaching magnetic saturation. Therefore, under the design conditions of (TMR1) to (TMR4), it is found that the ideal TMR element 51 can be obtained which can be used in the magnetic field ranges of 200 mT (magnetization of 0.99), 150 mT (magnetization of 0.95), 100 mT (magnetization of 0.96), and 50 mT (magnetization of 0.92), respectively.

The reason why the TMR element having ideal magnetization characteristics can be realized as described above is that the shape of the TMR element is designed such that perpendicular magnetization is substantially uniformly distributed in the free layer due to the shape magnetic anisotropy. For example, it is known that a disc-shaped TMR element having a diameter of 450 nm and a film thickness of 80 nm is of a vortex magnetization type, but when the z axis direction is set to the longitudinal direction and the effective size d is further small (for example, t>d), a magnetic moment distribution uniformly oriented in the z axis direction or a tornado-shaped magnetic moment distribution can be obtained. Furthermore, by setting the film thickness t of the free layer to 20 nm or more, the interface perpendicular magnetic anisotropy that causes nonlinearization becomes negligibly small. Here, in free layer (CoFeB)/tunnel layer (MgO), it is known that the interface perpendicular magnetic anisotropy becomes apparent when the film thickness of the free layer is about 1 to 2 nm or less (S. Ikeda et al., Nature Materials 9, 721 (2010)). From these considerations, all of (TMR1) to (TMR4) having the ideal characteristics illustrated in FIG. 5A have a magnetic moment distribution in which perpendicular magnetization is substantially uniformly distributed within the free layer due to the shape magnetic anisotropy.

FIG. 5B illustrates magnetization dynamics in the perpendicular magnetization type TMR element. It is assumed that the fixed layer 510 is magnetized in the horizontal direction (a direction of a white arrow). When an external magnetic field H (black arrow) is applied, the magnetic moment within the free layer 51q uniformly rotates (rotation angle θ), and magnetic saturation occurs as all of the magnetic moments are oriented in an in-plane direction (horizontal direction). Note that as described above, the resistance (also referred to as a magnetoresistance) of the TMR element 51 increases as the magnetic moment within the free layer 51q becomes antiparallel to the magnetic moment within the fixed layer 510, and decreases as the magnetic moment within the free layer 51q rotates due to the application of the external magnetic field and becomes parallel to the magnetic moment within the fixed layer.

A perpendicular component of the magnetic moment distribution in the perpendicular magnetization type TMR element in the present embodiment is due to the shape magnetic anisotropy, and a magnetization process is governed by the magnetostatic energy due to the external magnetic field and the demagnetizing field energy due to the shape magnetic anisotropy. In such a case, a total energy E per unit volume of the free layer 51q is given as a sum of the magnetostatic energy and the demagnetizing field energy, assuming that the interior of the free layer 51q is uniformly magnetized, that is,

$$E = Ms \times H \times sin θ - k \times {Ms}^{2} \times {cos}^{2} θ .$$

Herein, Ms is the saturation magnetization of the free layer 51q, H is the intensity of the external magnetic field applied to the free layer 51q in the horizontal direction, and θ is an angle of the magnetic moment with respect to the z axis direction (an in-plane perpendicular direction of the free layer 51q).

In addition, k is a parameter for giving the shape magnetic anisotropy, and depends on the shape of the free layer 51q. When the free layer 51q is long in the z axis direction (t>d), k<0 is satisfied.

The direction θ of the magnetic moment when the external magnetic field H is applied is determined so as to minimize the total energy E, and sin θ=−1/k×H/Ms is obtained from energy minimum conditions (∂E/∂θ=0 and ∂²E/∂θ²>0). Since this left side gives a magnetization component in the direction of the external magnetic field, the magnetization characteristic becomes linear with respect to an intensity H of the external magnetic field by designing the free layer 51q so as to have a substantially uniform perpendicular magnetization structure due to the shape magnetic anisotropy. Furthermore, by selecting design conditions, that is, a combination of the saturation magnetization Ms, the film thickness t, and the effective size d of the free layer 51q, the TMR element 51 can be obtained which has ideal magnetization characteristic that has linearity in a desired magnetic field range and substantially approaches magnetic saturation.

A condition of the perpendicular magnetization structure in which the magnetic moment within the free layer 51q is oriented substantially uniformly in the perpendicular direction due to the shape magnetic anisotropy is given as follows:
1) Aspect ratio of free layer (=film thickness t/effective size (diameter) d)≥1;
2) Film thickness t of free layer ≥20 nm; and
3) Effective size (diameter) d of free layer ≤2.57×10⁻² (A)/Ms (A/nm)).

Under Condition 1, the free layer 51q has a column shape, an effect of the shape magnetic anisotropy becomes dominant, and the magnetic moment within the free layer 51q is oriented in the perpendicular direction. Under Condition 2, an effect of a high-order component of the interface perpendicular magnetic anisotropy, which causes nonlinearization, becomes sufficiently small to be negligible, and the linearity of the magnetic susceptibility with respect to the intensity of the external magnetic field applied to the free layer 51q increases. Under Condition 3, the magnetic moment within free layer 51q does not form a vortex magnetization structure. Here, it is known that a minimum radius (d/2) at which the vortex magnetization becomes a most stable structure is on the order of an exchange length (=√(A/(μ₀×Ms²)=3.2×10⁶ (A)/Ms (A/nm)), where μ₀ is the vacuum permeability, A is the exchange stiffness (=1.3×10⁻²⁰ J/nm), and Ms is the saturation magnetization). Here, the exchange length is a critical value of a length at which the exchange interaction, which tends to align orientations of adjacent magnetic moments, is dominant. In addition, it is known that, in the free layer 51q having an aspect ratio of about 1, the vortex magnetization occurs when the radius is equal to or greater than 4 times the exchange length (Sato et al., Journal of the Magnetics Society of Japan 36, 173 (2012)). Under these conditions, the free layer 51q can be formed which has a perpendicular magnetization structure in which the magnetic moment is uniformly or substantially uniformly oriented in the z axis direction, whereby the TMR element 51 can be obtained which has high sensitivity in a wide magnetic field range.

Note that in Condition 3, ½ of the effective size (diameter) d of the free layer 51q may be equal to or less than 4 times the exchange length within the free layer 51q. According to this, since ½ of the effective size d is equal to or less than 4 times, preferably equal to or less than 3 times, more preferably equal to or less than 2 times, and still more preferably equal to or less than 1 time the exchange length (exchange coupling length) within the free layer 51q, the magnetic moment within the free layer 51q does not form the vortex magnetization structure, and the free layer 51q can be formed which has a perpendicular magnetization structure in which the magnetic moment is uniformly or substantially uniformly oriented in the z axis direction, whereby the TMR element can be obtained which has high sensitivity in a wide magnetic field range.

Furthermore, based on processability of the TMR element, additional conditions are given as follows:
4) Effective size d≥20 nm; and
5) Film thickness t≤200 nm.

Under Condition 4 facilitates formation of the free layer 51q in a column shape. Under Condition 5 facilitates etching of the free layer 51q, thereby improving processability of the free layer 51q (European Patent Application Publication No. 4198541). Note that the film thickness t is not limited to 200 nm or less, and may be 180 nm or less, preferably 140 nm or less, more preferably 100 nm or less, still more preferably 80 nm or less, and still more preferably 60 nm or less. Under Conditions 1 to 5, a TMR element is obtained which has excellent processability and has ideal magnetization characteristics from a viewpoint of a magnetic field range and sensitivity.

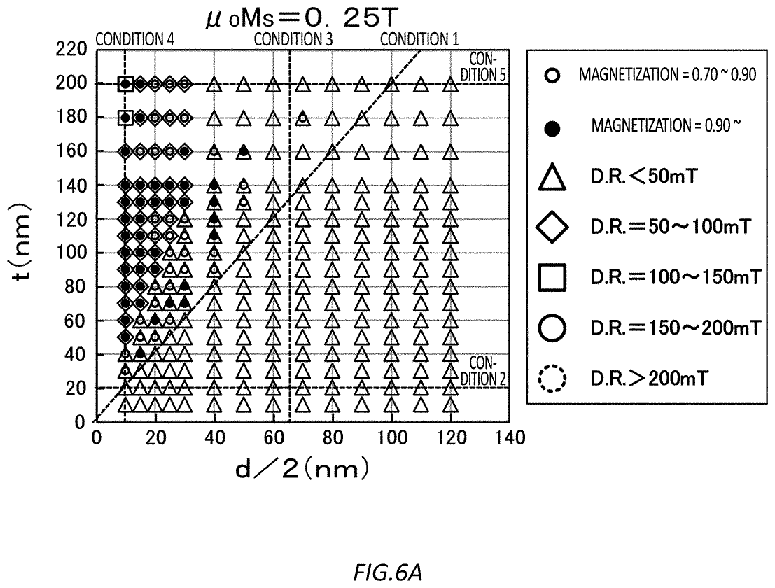

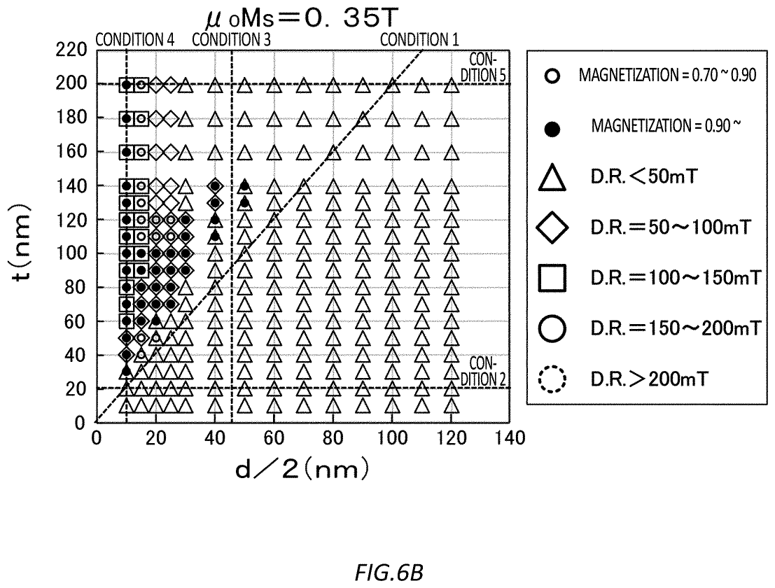

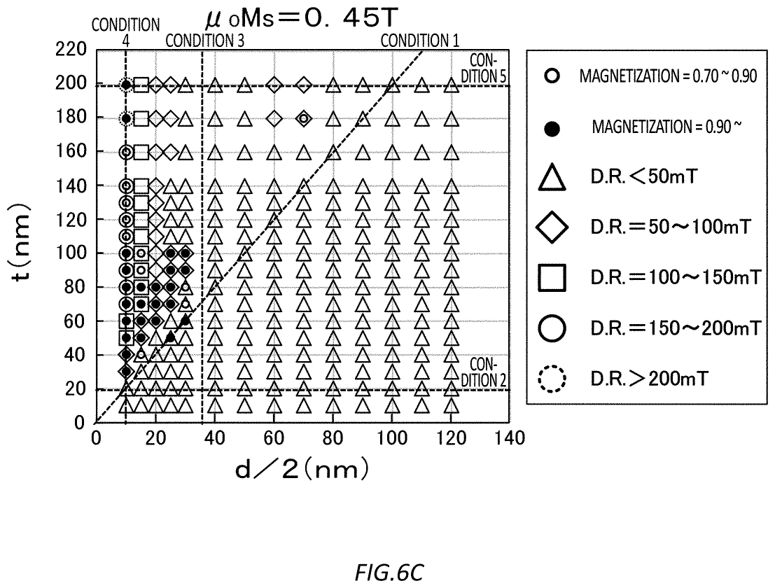

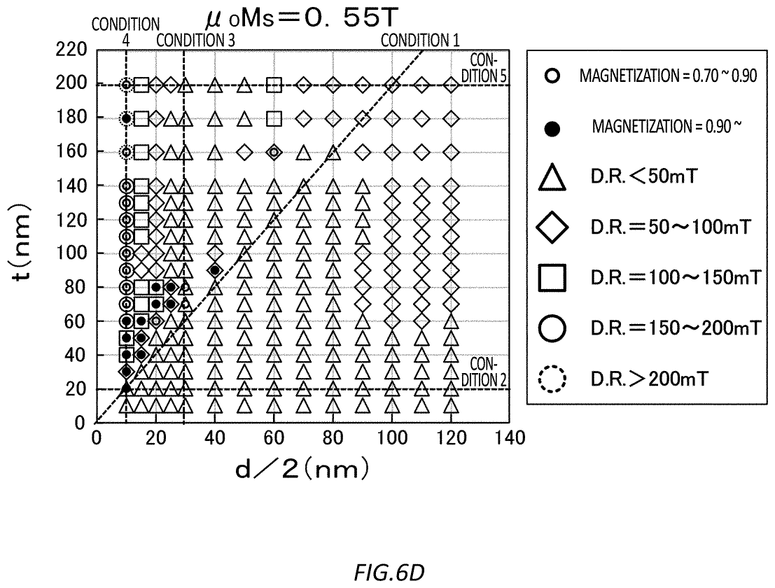

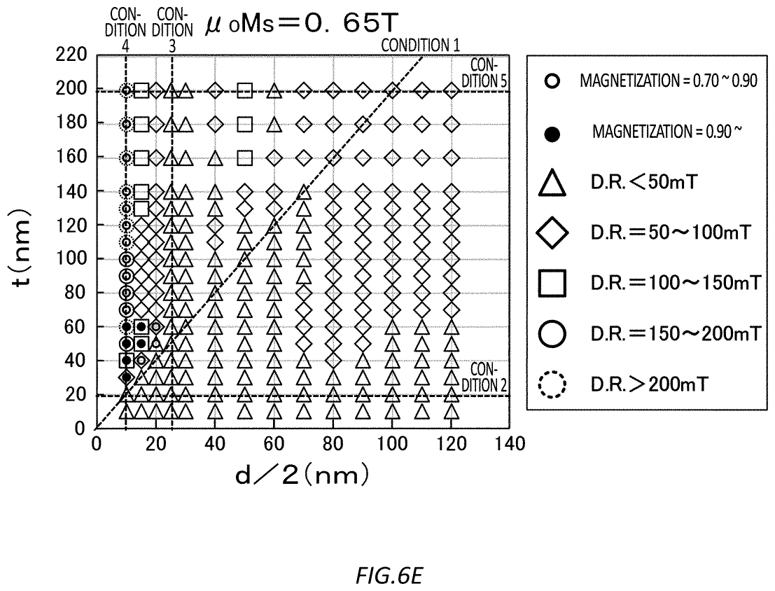

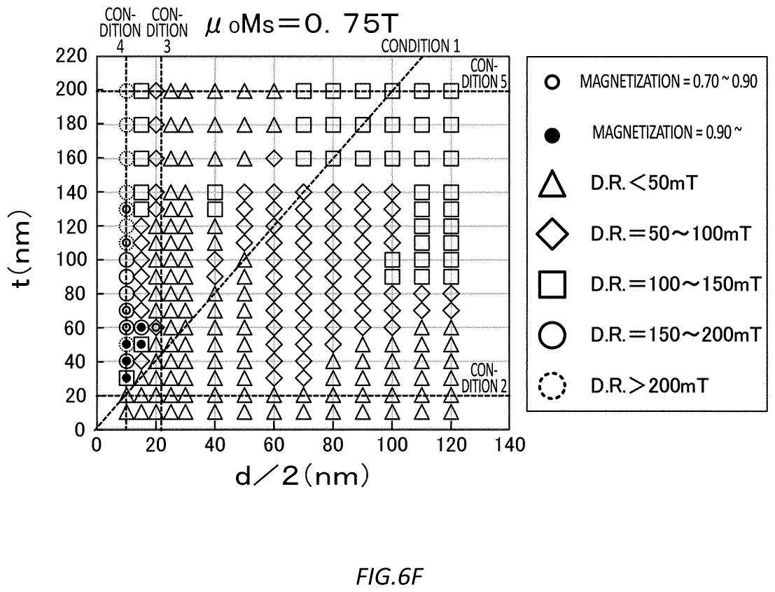

FIGS. 6A to 6F illustrate some examples of a design map of an ideal-characteristic TMR element. It is assumed that the free layer 51q has a circular cross section, that is, a cylindrical shape. A micromagnetic simulation was performed with respect to a combination of the saturation magnetization μ₀Ms, the film thickness t, and the effective size (diameter) d to calculate a magnetic field range (denoted as D.R. in the drawing) with a nonlinearity error of 1% or less and a magnetic susceptibility (simply referred to as magnetization in the drawing) within the range. For each combination of the saturation magnetization μ₀Ms, the film thickness t, and the effective size d, the obtained magnetic field range (D.R.) of <50 mT is represented by a triangle, the magnetic field range of 50 to 100 mT is represented by a rhombus, the magnetic field range of 100 to 150 mT is represented by a square, the magnetic field range of 150 to 200 mT is represented by a solid circle, and the magnetic field range of 200 mT or more is represented by a dotted circle, and the obtained magnetic susceptibility of 0.70 to 0.90 is represented by a small white circle, the magnetic susceptibility of at least 0.90 are represented by a small black circle, and the magnetic susceptibility of less than 0.70 is represented without symbols. Note that for the saturation magnetization μ₀Ms=x(T), Ms is expressed as Ms=x/μ₀ (A/m)=(x×10⁻⁹)/μ₀ (A/nm).

FIG. 6A illustrates a design map for saturation magnetization μ₀Ms=0.25 T. Reference lines corresponding to Conditions 1 to 5 are described in the map. A magnetic field range of 50 to 100 mT is obtained in an upper left region satisfying Conditions 1 and 2, particularly in a region where effective size d/2 is 30 nm or less. On the other hand, in a lower right region (t/d<1) not satisfying these conditions, the magnetic field range is 50 mT or less. Further, a high magnetic susceptibility of 0.7 or more is obtained in a left region of the reference line satisfying Condition 3 (d/2≤65 nm), and further a higher magnetic susceptibility of 0.9 or more is obtained when film thickness t≤about 140 nm. It is found that a TMR element having a wide magnetic field range of approximately 50 to 100 mT and a high magnetic susceptibility of 0.7 or more can be designed within a region satisfying Conditions 4 and 5 of the processability.

FIG. 6B illustrates a design map for saturation magnetization μ₀Ms=0.35 T. Reference lines corresponding to Conditions 1 to 5 are described in the map. A magnetic field range of 50 to 150 mT is obtained in an upper left region satisfying Conditions 1 and 2, particularly in a region where effective size d/2 is 30 nm or less. On the other hand, in a lower right region (t/d<1) not satisfying these conditions, the magnetic field range is 50 mT or less. Further, a high magnetic susceptibility of 0.7 or more is obtained in a left region of the reference line satisfying Condition 3 (d/2≤46 nm), and further a higher magnetic susceptibility of 0.9 or more is obtained when film thickness t≤about 140 nm. It is found that a TMR element having a wide magnetic field range of approximately 50 to 150 mT and a high magnetic susceptibility of 0.7 or more can be designed within a region satisfying Conditions 4 and 5 of the processability. In addition, the magnetic field range is shifted to a high magnetic field side with respect to the saturation magnetization μ₀Ms=0.25 T illustrated in FIG. 6A.

FIG. 6C illustrates a design map for saturation magnetization μ₀Ms=0.45 T. Reference lines corresponding to Conditions 1 to 5 are described in the map. A magnetic field range of 50 to 200 mT is obtained in an upper left region satisfying Conditions 1 and 2, particularly in a region where effective size d/2 is 30 nm or less. On the other hand, in a lower right region (t/d<1) not satisfying these conditions, the magnetic field range is 50 mT or less. Further, a high magnetic susceptibility of 0.7 or more is obtained in a left region of the reference line satisfying Condition 3 (d/2≤36 nm), and further a higher magnetic susceptibility of 0.9 or more is obtained when film thickness t≤about 100 nm. It is found that a TMR element having a wide magnetic field range of approximately 50 to 200 mT and a high magnetic susceptibility of 0.7 or more can be designed within a region satisfying Conditions 4 and 5 of the processability. In addition, the magnetic field range is shifted to a high magnetic field side with respect to the saturation magnetization μ₀Ms=0.35 T illustrated in FIG. 6B.

FIG. 6D illustrates a design map for saturation magnetization μ₀Ms=0.55 T. Reference lines corresponding to Conditions 1 to 5 are described in the map. A magnetic field range of 50 to 200 mT is obtained in an upper left region satisfying Conditions 1 and 2, particularly in a region where effective size d/2 is 30 nm or less. Further, a high magnetic susceptibility of 0.7 or more is obtained in a left region of the reference line satisfying Condition 3 (d/2≤29 nm), and further a higher magnetic susceptibility of 0.9 or more is obtained when film thickness t≤about 80 nm. It is found that a TMR element having a wide magnetic field range of approximately 50 to 200 mT and a high magnetic susceptibility of 0.7 or more can be designed within a region satisfying Conditions 4 and 5 of the processability.

FIG. 6E illustrates a design map for saturation magnetization μ₀Ms=0.65 T. Reference lines corresponding to Conditions 1 to 5 are described in the map. A magnetic field range of 50 to 200 mT is obtained in an upper left region satisfying Conditions 1 and 2, particularly in a region where effective size d/2 is 20 nm or less. Further, a high magnetic susceptibility of 0.7 or more is obtained in a left region of the reference line satisfying Condition 3 (d/2≤25 nm), and further a higher magnetic susceptibility of 0.9 or more is obtained when film thickness t≤about 60 nm. It is found that a TMR element having a wide magnetic field range of approximately 50 to 200 mT and a high magnetic susceptibility of 0.7 or more can be designed within a region satisfying Conditions 4 and 5 of the processability.

FIG. 6F illustrates a design map for saturation magnetization μ₀Ms=0.75 T. Reference lines corresponding to Conditions 1 to 5 are described in the map. A magnetic field range of 50 to 200 mT is obtained in an upper left region satisfying Conditions 1 and 2, particularly in a region where effective size d/2 is 20 nm or less. Further, a high magnetic susceptibility of 0.7 or more is obtained in a left region of the reference line satisfying Condition 3 (d≤21 nm), and further a higher magnetic susceptibility of 0.9 or more is obtained when film thickness t≤about 60 nm. It is found that a TMR element having a wide magnetic field range of approximately 50 to 200 mT and a high magnetic susceptibility of 0.7 or more can be designed within a region satisfying Conditions 4 and 5 of the processability.

Therefore, the TMR element can be obtained which is substantially magnetically saturated in a wide magnetic field range of 50 to 200 mT under Conditions 1 to 5, that is, exhibits ideal magnetization characteristics having a high sensitivity of a magnetic susceptibility of 0.7 or more. Note that in order to obtain the free layer 51q satisfying Conditions 1 to 5, the saturation magnetization may be set to 0.65 T or less.

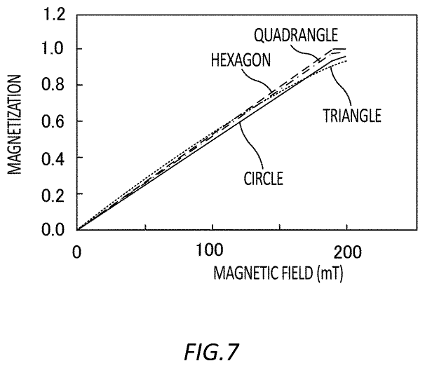

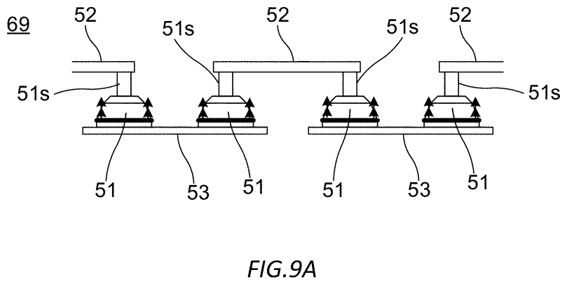

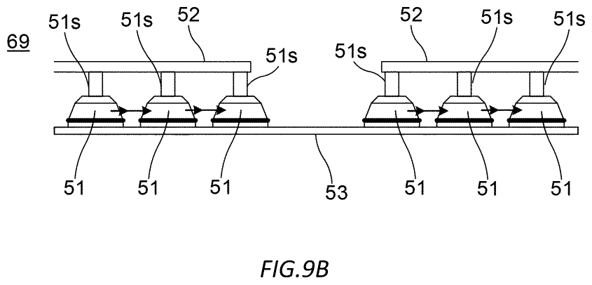

FIG. 7 illustrates magnetization characteristics of the TMR element having a polygonal cross section. Here, the free layer 51q was assumed to have a polygonal column shape having a triangular cross section, a quadrangular (square) cross section, and a hexagonal cross section. It is assumed that saturation magnetization μ₀Ms=0.35 T, effective size d=40 nm, and film thickness t=60 nm. The magnetization characteristics in a case of a cylindrical shape having a circular cross section are also illustrated. The magnetization characteristic increases almost linearly as the intensity of the external magnetic field increases, and is saturated (magnetic saturation) to a constant value when the intensity of the external magnetic field exceeds a given saturation magnetic field. Here, the magnetization characteristics in a case of the quadrangular cross section and the hexagonal cross section exhibit somewhat better sensitivity than the magnetization characteristics in the case of the circular cross section. The magnetization characteristics in a case of the triangular cross section also have some nonlinearity, but exhibit somewhat better sensitivity than the magnetization characteristics in the case of the circular cross section. Therefore, even in a case of a polygonal cross section having an equal effective size, it is possible to reproduce the magnetization characteristics in the case of the circular cross section within a deviation range of several percent. According to the design of the free layer 51q of the TMR element 51 in the present embodiment, the demagnetizing field energy is reduced and stabilization is achieved by aligning the magnetization parallel to the side surface of the free layer 51q due to the shape magnetic anisotropy (see FIG. 9A). Therefore, the magnetization characteristics of the TMR element 51 do not depend on the cross-sectional shape of the free layer 51q.

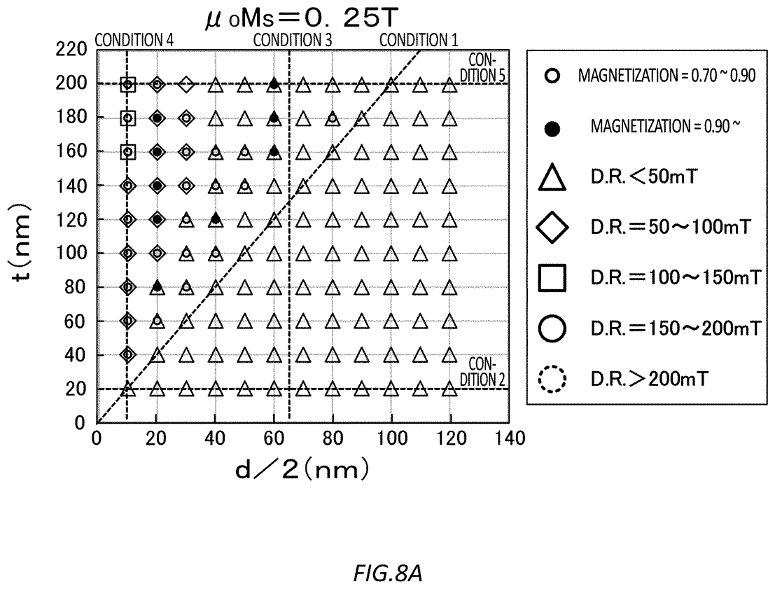

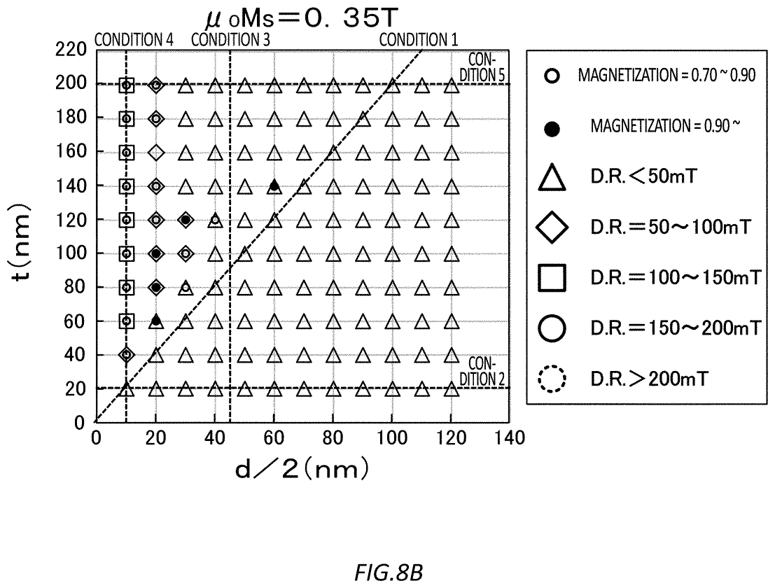

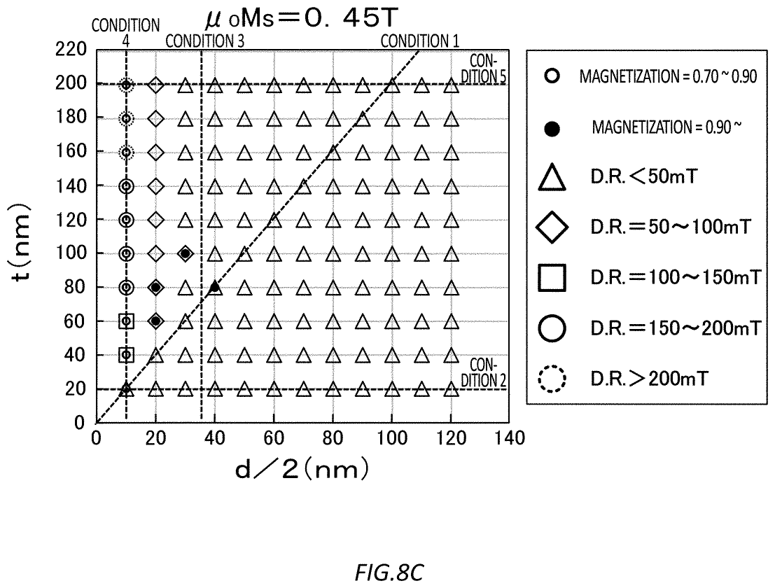

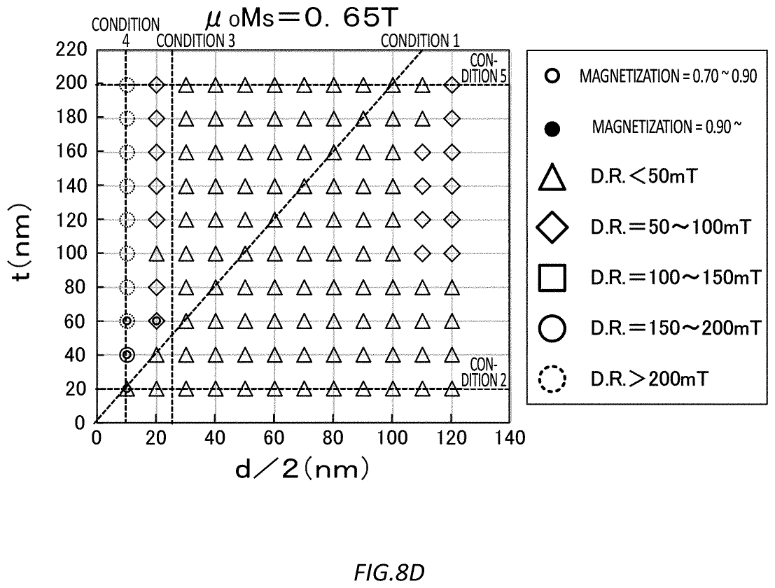

FIGS. 8A to 8D illustrate some examples of the design map of the ideal-characteristic TMR element. It is assumed that the free layer 51q has a square cross section, that is, a quadrangular prism shape. A micromagnetic simulation was performed with respect to a combination of the saturation magnetization μ₀Ms, the film thickness t, and the effective size (diameter) d to calculate a magnetic field range (denoted as D.R. in the drawing) with a nonlinearity error of 1% or less and a magnetic susceptibility (simply referred to as magnetization in the drawing) within the range. For each combination of the saturation magnetization μ₀Ms, the film thickness t, and the effective size d, the obtained magnetic field range (D.R.) of <50 mT is represented by a triangle, the magnetic field range of 50 to 100 mT is represented by a rhombus, the magnetic field range of 100 to 150 mT is represented by a square, the magnetic field range of 150 to 200 mT is represented by a solid circle, and the magnetic field range of 200 mT or more is represented by a dotted circle, and the obtained magnetic susceptibility of 0.70 to 0.90 is represented by a small white circle, the magnetic susceptibility of at least 0.90 are represented by a small black circle, and the magnetic susceptibility of less than 0.70 is represented without symbols.

FIG. 8A illustrates a design map for saturation magnetization μ₀Ms=0.25 T. Reference lines corresponding to Conditions 1 to 5 are described in the map. A magnetic field range of 50 to 150 mT is obtained in an upper left region satisfying Conditions 1 and 2, particularly in a region where effective size d/2 is 30 nm or less. On the other hand, in a lower right region (t/d<1) not satisfying these conditions, the magnetic field range is 50 mT or less. Further, a high magnetic susceptibility of 0.7 or more is obtained in a left region of the reference line satisfying Condition 3 (d/2≤65 nm), and further a higher magnetic susceptibility of 0.9 or more is obtained when effective size d/2≤20 nm and film thickness t≤about 120 to 180 nm. It is found that a TMR element having a wide magnetic field range of approximately 50 to 150 mT and a high magnetic susceptibility of 0.7 or more can be designed within a region satisfying Conditions 4 and 5 of the processability.

FIG. 8B illustrates a design map for saturation magnetization μ₀Ms=0.35 T. Reference lines corresponding to Conditions 1 to 5 are described in the map. A magnetic field range of 50 to 150 mT is obtained in an upper left region satisfying Conditions 1 and 2, particularly in a region where effective size d/2 is 30 nm or less. On the other hand, in a lower right region (t/d<1) not satisfying these conditions, the magnetic field range is 50 mT or less. Further, a high magnetic susceptibility of 0.7 or more is obtained in a left region of the reference line satisfying Condition 3 (d/2≤46 nm), and further a higher magnetic susceptibility of 0.9 or more is obtained when effective size d/2≤20 nm and film thickness t≤about 60 to 100 nm. It is found that a TMR element having a wide magnetic field range of approximately 50 to 150 mT and a high magnetic susceptibility of 0.7 or more can be designed within a region satisfying Conditions 4 and 5 of the processability.

FIG. 8C illustrates a design map for saturation magnetization μ₀Ms=0.45 T. Reference lines corresponding to Conditions 1 to 5 are described in the map. A magnetic field range of 50 to 200 mT is obtained in an upper left region satisfying Conditions 1 and 2, particularly in a region where effective size d/2 is 30 nm or less. Further, a high magnetic susceptibility of 0.7 or more is obtained in a left region of the reference line satisfying Condition 3 (d/2≤36 nm), and further a higher magnetic susceptibility of 0.9 or more is obtained when effective size d/2≤20 to 30 nm and film thickness t≤about 60 to 100 nm. It is found that a TMR element having a wide magnetic field range of approximately 50 to 200 mT and a high magnetic susceptibility of 0.7 or more can be designed within a region satisfying Conditions 4 and 5 of the processability. In addition, the magnetic field range is shifted to a high magnetic field side with respect to the saturation magnetization μ₀Ms=0.35 T illustrated in FIG. 8B.

FIG. 8D illustrates a design map for saturation magnetization μ₀Ms=0.65 T. Reference lines corresponding to Conditions 1 to 5 are described in the map. A magnetic field range of 50 to 200 mT is obtained in an upper left region satisfying Conditions 1 and 2, particularly in a region where effective size d/2 is 20 nm or less. Further, in a left region of the reference line satisfying Condition 3 (d/2≤29 nm), a high magnetic susceptibility of 0.7 or more is obtained when the film thickness t≤about 40 to 60 nm. It is found that a TMR element having a wide magnetic field range of approximately 50 to 200 mT and a high magnetic susceptibility of 0.7 or more can be designed within a region satisfying Conditions 4 and 5 of the processability.

Therefore, even in the TMR element 51 in which the free layer 51q has a quadrangular cross section, the TMR element 51 can be obtained which is substantially magnetically saturated in a wide magnetic field range of 50 to 200 mT under Conditions 1 to 5, that is, exhibits ideal magnetization characteristics having high sensitivity of a magnetic susceptibility of 0.7 or more. Note that in order to obtain the free layer 51q satisfying Conditions 1 to 5, the saturation magnetization may be set to 0.65 T or less.

In addition, the magnetic moment within the fixed layer may be oriented in a planar direction intersecting the uniaxial direction, that is, horizontal magnetization. Since the fixed layer has horizontal magnetization and the free layer has perpendicular magnetization, a tunnel magnetoresistance element functions as an element for a magnetic sensor. Here, the magnetization direction of the fixed layer can be specified based on electrical characteristics. That is, when a transverse magnetic field and a longitudinal magnetic field are made incident on the magnetoresistance element, and a magnetoresistance change ΔR with respect to the magnetic field is any of following two patterns, it can be specified that the magnetization direction of the fixed layer is the perpendicular direction. Pattern 1 of the two patterns is a case where the free layer is longitudinally magnetized and the fixed layer is longitudinally magnetized, and shows a characteristic that the magnetoresistance change ΔR exhibits a hysteresis characteristic when the longitudinal magnetic field is applied to the magnetoresistance element, and the magnetoresistance change ΔR increases in proportion to an absolute value of the intensity of the transverse magnetic field when the transverse magnetic field is applied. Pattern 2 is a case where the free layer is transversely magnetized and the fixed layer is longitudinally magnetized, and shows a characteristic that the magnetoresistance change ΔR increases in proportion to the intensity of the longitudinal magnetic field when the longitudinal magnetic field is applied to the magnetoresistance element, and the magnetoresistance change ΔR maintains zero without depending on the intensity of the transverse magnetic field when the transverse magnetic field is applied. In addition, the magnetization direction of the fixed layer can also be specified by physical analysis. As an analysis method, for example, a Lorentz electron microscope (LTEM), a magneto-optical Kerr effect microscope (MOKE), a spin-polarized scanning tunneling microscope (SP-STM), a magnetic force microscope (MFM), or a spin-polarized low-speed electron microscope (SPLEEM) can be used.

At least two TMR elements 51 may be arranged on a same plane and connected in a single row and/or in parallel between two electrode pieces 52 and 53 to form a magnetic sensor module (also referred to as a TMR module) 69.

FIGS. 9A and 9B illustrate configuration examples of a single-row module and a parallel module of the TMR element 51, respectively. According to the design maps illustrated in FIGS. 6A to 6F, when the design condition of the TMR element is selected such that ideal magnetization characteristics are obtained in a relatively small magnetic field range of 50 to 100 mT, the design condition approaches a design condition for giving non-ideal magnetization characteristics having a magnetic field range of 50 mT or less and a magnetic susceptibility of 0.7 or less. Therefore, when the single-row module is constituted by using the plurality of TMR elements 51 and the electrode pieces 52 and 53 as illustrated in FIG. 9A, there is a probability that the module is configured including a TMR element having non-ideal magnetization characteristics due to a manufacturing tolerance. In this regard, as illustrated in FIG. 9B, a plurality of (at least two, and in the present example, three) TMR elements 51 may be arranged on the same plane and connected in parallel between two electrode pieces 52 and 53. As indicated by arrows in the drawing, each magnetic moment terminates between adjacent TMRs 51, thereby relaxing the shape magnetic anisotropy while maintaining a high magnetic susceptibility (high sensitivity), making it possible to achieve a low magnetic field range. However, even when the magnetic field range decreases, the magnetic susceptibility of 0.9 or more is maintained.

As described above, by connecting the plurality of TMR elements 51 in parallel to be modularized, it is not necessary to provide an enclosure in the electrode piece 53 which is a lower electrode, and it is possible to integrate the TMR elements 51. Here, the enclosure is a barrier configured to prevent burrs, which are generated at the end portion of the electrode piece 53 during ion beam etching of the TMR element 51, from coming into contact with the free layer 51q and causing a short circuit. By integrating the TMR element 51, it is possible to suppress a chip area, a wiring parasitic resistance, and a magnetic flux interlinking wirings, that is, a di/dt noise. Furthermore, by connecting the TMR elements 51 in parallel, it is possible to suppress 1/f noise and thermal noise.

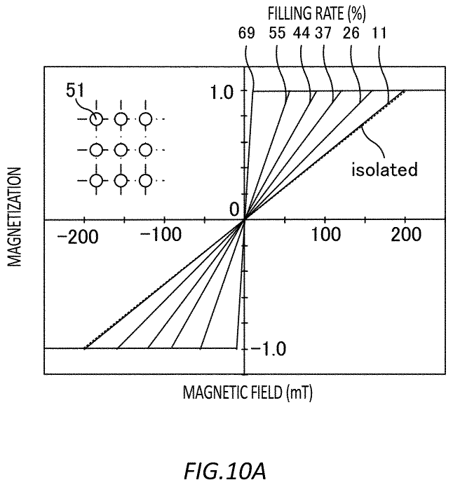

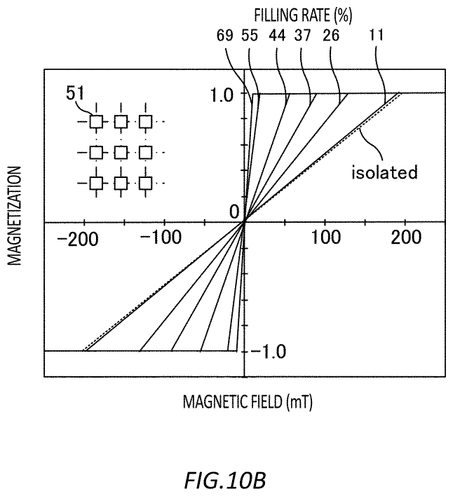

FIG. 10A illustrates filling rate dependency of magnetization characteristics of the TMR module 69 formed by using a plurality of TMR elements 51. Each TMR element 51 includes the free layer 51q having a cylindrical shape with a circular cross section, and has the saturation magnetization μ₀Ms=0.75 T, the effective size d=30 nm, and the film thickness t=60 nm. A magnetization characteristic (isolated) when one TMR element 51 is isolated and a magnetization characteristic (filling rates of 11, 26, 37, 44, 55, 69%) when the TMR elements 51 are modularized by being periodically arrayed in an x direction and a y direction intersecting with each other in a horizontal plane in plan view are illustrated. Here, the filling rate of the TMR element 51 can be given as a proportion of an area occupied by the TMR elements 51 on the plane on which the plurality of TMR elements 51 are arranged.

The isolated TMR element 51 increases (increases in a negative direction) as the intensity of the external magnetic field increases (increases in the negative direction), and is magnetically saturated at 200 mT (−200 mT). On the other hand, the magnetization characteristic in the TMR module 69 increases (increases in the negative direction) as the intensity of the external magnetic field increases (increases in the negative direction), and magnetic saturation occurs at a lower magnetic field intensity than in a case of isolation. Here, the external magnetic field intensities at which magnetic saturation occurs are about 200, 160, 120, 90, 60, and 10 mT for the filling rates of 11, 26, 37, 44, 55, and 69%, respectively. Therefore, by modularizing and increasing the filling rate of the TMR element 51, the magnetic field range can be decreased, and the sensitivity can be increased. Note that even when the magnetic field range is decreased, the magnetic susceptibility of 0.9 or more is maintained.

FIG. 10B illustrates the filling rate dependency of the magnetization characteristics of the TMR module 69 formed by using the plurality of TMR elements 51. Each TMR element 51 includes the free layer 51q having a prismatic shape with a square cross section, and has the saturation magnetization μ₀Ms=0.75 T, the effective size d=30 nm, and the film thickness t=60 nm. A magnetization characteristic (isolated) when one TMR element 51 is isolated and a magnetization characteristic (filling rates of 11, 26, 37, 44, 55, 69%) when the TMR elements 51 are modularized by being periodically arrayed in an x direction and a y direction intersecting with each other in a horizontal plane in plan view are illustrated. Here, the filling rate of the TMR element 51 can be given as a proportion of an area occupied by the TMR elements 51 on the plane on which the plurality of TMR elements 51 are arranged.

The isolated TMR element 51 increases (increases in a negative direction) as the intensity of the external magnetic field increases (increases in the negative direction), and is magnetically saturated at 200 mT (−200 mT). On the other hand, the magnetization characteristic in the TMR module 69 increases (increases in the negative direction) as the intensity of the external magnetic field increases (increases in the negative direction), and magnetic saturation occurs at a lower magnetic field intensity than in a case of isolation. Here, the external magnetic field intensities at which magnetic saturation occurs are about 190, 130, 90, 60, 20, and 10 mT for the filling rates of 11, 26, 37, 44, 55, and 69%, respectively. Therefore, by modularizing using the TMR element 51 having a circular cross section to increase the filling rate of the TMR element 51, the magnetic field range can be decreased and the sensitivity can be increased. Note that even when the magnetic field range is decreased, the magnetic susceptibility of 0.9 or more is maintained.

As described above, the area filling rate of the TMR element 51 on the same plane is set to 11 to 55%. Note that the area filling rate is 11% or more, preferably 26% or more, more preferably 37% or more, still more preferably 44% or more and 55% or less, for example, preferably 11% or more and 55% or less. According to this, by increasing the area filling rate of the TMR element 51 to 11 to 55%, the magnetic field range can be decreased, and the sensitivity can be increased. In particular, by setting the area filling rate to 55% or less, the sensitivity can be adjusted so that the magnetic field range is 50 mT or more. Note that the filling rate of 11 to 55% corresponds to a distance dx=dy=4 nm to 25 nm between two adjacent TMR elements 51 on the same plane.

The magnetic sensor module 69 may be formed by using a plurality of TMR elements 51 having one or more types of polygonal free layers 51q that allow for close-packing.

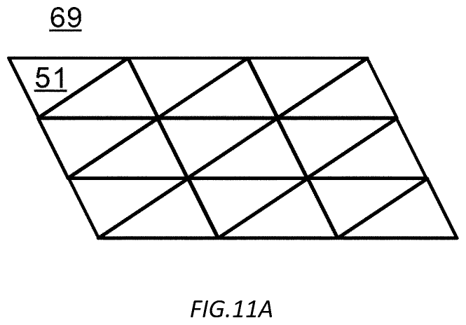

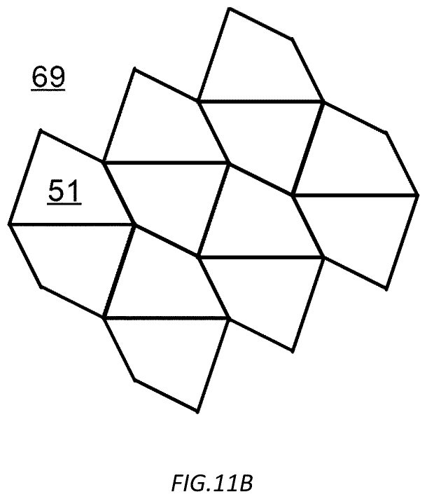

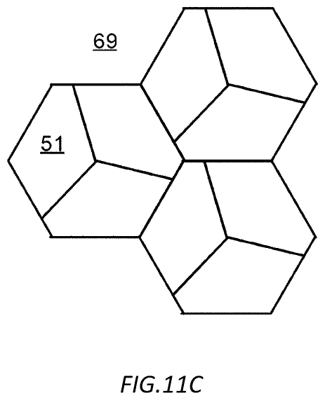

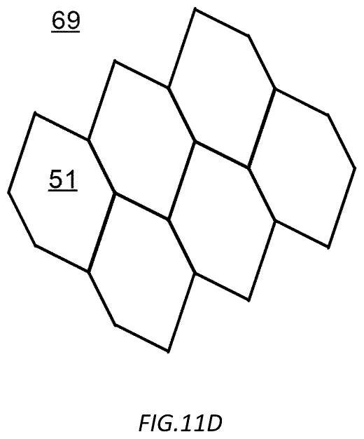

FIGS. 11A to 11D illustrate examples of a cross-sectional shape and array of the TMR elements 51 constituting the TMR module 69 (examples of a single shape). Here, FIG. 11A illustrates an example of a cross-sectional shape and array of triangles, FIG. 11B illustrates an example of a cross-sectional shape and array of quadrangles, FIG. 11C illustrates an example of a cross-sectional shape and array of pentagons, and FIG. 11D illustrates an example of a cross-sectional shape and array of hexagons. By forming each TMR element 51 into a polygonal shape that allows for fine-packing, an integration rate of the modules can be improved as compared with the case of the circular cross section. In addition, by adopting a polygonal shape having a large number of angles, an acute angle portion is eliminated, and processing becomes easy.

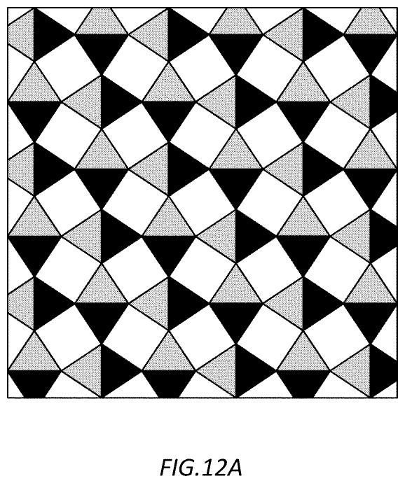

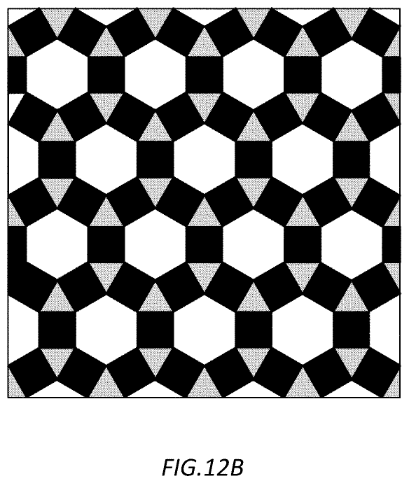

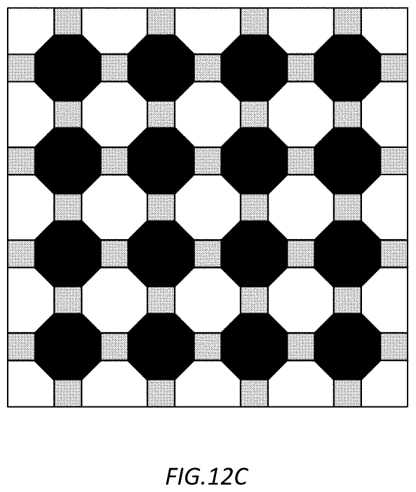

FIGS. 12A to 12C illustrate examples of the cross-sectional shape and the array of the TMR elements 51 constituting the TMR module 69 (examples of multiple shapes). Here, FIG. 12A illustrates an example of a combination of cross-sectional shapes and array of triangles and quadrangles, FIG. 12B illustrates an example of a combination of cross-sectional shapes and array of triangles, quadrangles, and hexagons, and FIG. 12C illustrates an example of a combination of cross-sectional shapes and array of quadrangles and octagons. The TMR elements 51 having the same cross-sectional shape may be connected in series or in parallel to form a sub-module, and the sub-modules may be connected in parallel or in series to form the TMR module 69.

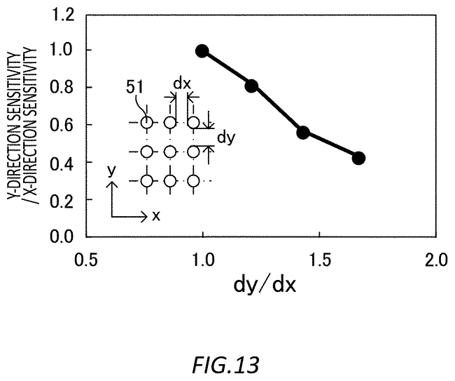

FIG. 13 illustrates sensitivity selectivity of the TMR module 69. In the TMR module 69, the plurality of TMR elements 51 are periodically arrayed in the y axis direction and the x axis direction on the same plane, and an array pitch (distance dy) of the TMR elements 51 in the y axis direction is larger than an array pitch (distance dx) in the x axis direction (dy>dx). Each TMR element 51 includes the free layer 51q having a cylindrical shape with a circular cross section, and has the saturation magnetization μ₀Ms=0.75 T, the effective size d=30 nm, and the film thickness t=60 nm. It can be seen that as an array pitch ratio (distance ratio dy/dx) increases, the sensitivity of the TMR module 69 to the external magnetic field in the y axis direction decreases relatively to the sensitivity to the external magnetic field in the x axis direction. Therefore, since the array pitch of the TMR elements 51 in the y axis direction is larger than the array pitch in the x axis direction, the sensitivity of the TMR module 69 to the external magnetic field in the y axis direction is smaller than the sensitivity to the external magnetic field in the x axis direction, and the external magnetic field in the x axis direction can be accurately measured.

In the current sensor 110, the TMR module 69 is preferably insensitive to the disturbance magnetic field (a magnetic field other than that generated by the current to be measured). For example, when a magnetic field Bx in the x axis direction is generated by the current to be measured flowing inside the bus bar 24 in the y axis direction, a sensitivity to a magnetic field By in the y axis direction is desirably lower than a sensitivity to the magnetic field Bx. By appropriately designing the array pitches of the TMR module 69 in the x axis direction and the y axis direction, it is possible to provide the sensitivity with selectivity. Furthermore, the current sensor 110 may be formed by arranging the TMR module 69 such that the y axis direction is parallel to the direction of the current to be measured flowing through the bus bar 24.

The TMR element 51 according to the present embodiment includes the fixed layer 510, the insulating layer 51p, and the free layer 51q which are sequentially stacked in the z axis direction, the free layer 51q has a column shape extending in the z axis direction and spreading in the horizontal direction, and with the height t of the free layer 51q in the z axis direction and the effective size d of the free layer 51q with respect to spread in the horizontal direction, the aspect ratio (t/d), given using the height (film thickness) t and the effective size d, is 1 or more, the height t is 20 nm or more, and the effective size d is 2.57×10⁻² (A)/Ms or less, with the saturation magnetization Ms (A/nm) of the free layer. According to this, the free layer 51q forming the TMR element 51 has a column shape, by setting the height t and the effective size d of the free layer 51q such that the aspect ratio (t/d) is 1 or more, the magnetic moment within the free layer 51q is oriented in the z axis direction due to the shape magnetic anisotropy, by setting the height t to 20 nm or more, the interface perpendicular magnetic anisotropy becomes sufficiently small to be negligible, that is, the effect of its high-order component becomes sufficiently small to be negligible, thereby increasing the linearity of the magnetic susceptibility with respect to the intensity of the external magnetic field applied to the free layer 51q, and by setting the effective size d to 2.57×10⁻² (A)/Ms (A/nm) or less, it is possible to form the free layer 51q having a perpendicular magnetization structure in which the magnetic moment within the free layer 51q is oriented uniformly or substantially uniformly in the z axis direction without forming the vortex magnetization structure, whereby it is possible to obtain the TMR element with high sensitivity in a wide magnetic field range.

Note that the TMR element 51 may be a perpendicular magnetization type or tornado type TMR element including the fixed layer 510, the insulating layer 51p, and the free layer 51q sequentially stacked in the z axis direction, in which the free layer 51q has a column shape extending in the z axis direction and spreading in the horizontal direction, and the magnetic moment within the free layer 51q is oriented in the z axis direction or oriented in a direction inclined circumferentially about the central axis of the column shape with respect to the z axis direction. When the magnetic moment within the free layer 51q is oriented in the z axis direction or becomes a tornado shape, a TMR element having high sensitivity in a wide magnetic field range can be obtained.

The magnetic sensor module (TMR module) 69 according to the present embodiment includes at least two TMR elements 51 arranged on the same plane and connected in parallel between two electrodes 52 and 53.

The current sensor 110 according to the present embodiment includes the magnetic sensor module 69 arranged on a U-shaped or substantially U-shaped bus bar, and the x axis direction is parallel to the direction of the current to be measured flowing through the bus bar 24. According to this, in the current sensor 110 in which the magnetic sensor module 69 is arranged on the U-shaped or substantially U-shaped bus bar, an amount of current flowing through the bus bar 24 can be detected with high accuracy by making the array pitch of the TMR elements 51 with respect to the direction of the current to be measured flowing through the bus bar 24 larger than the array pitch of the TMR elements 51 with respect to the direction intersecting the direction of the current.

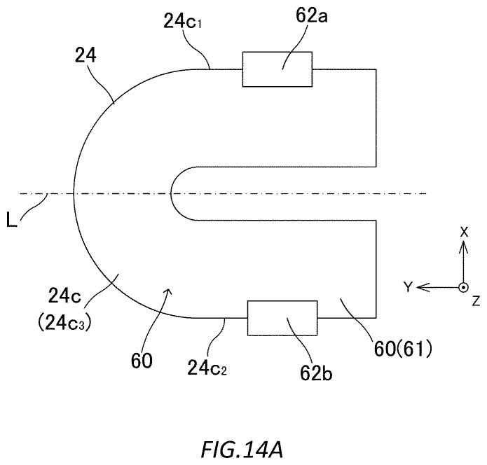

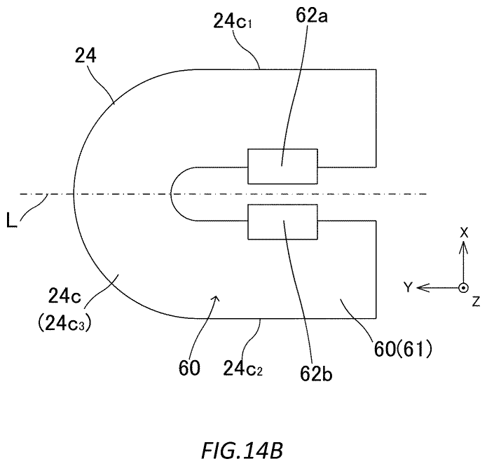

Note that the TMR element 51 having sensitivity in a horizontal plane may be arranged at a location where the horizontal magnetic field is generated within the package of the current sensor 110, that is, at a location where there is no perpendicular magnetic field. Since the TMR element 51 has strong shape magnetic anisotropy in the perpendicular direction, a configuration that is hardly affected by the magnetic field in the perpendicular direction is more desirable. The TMR element 51 can be implemented by at least partially overlapping the U-shaped or substantially U-shaped bus bar 24 in plan view as illustrated in FIGS. 14A and 14B, and preferably by being arranged at a center of the bus bar 24 in the width direction as illustrated in FIG. 2A.

Note that by including a magnetic sensor module in which a plurality of TMR elements 51 are arranged on the same plane and connected between two electrodes, it is also possible to provide the current sensor 110 exhibiting duplex or multiple linearity according to the current to be measured.

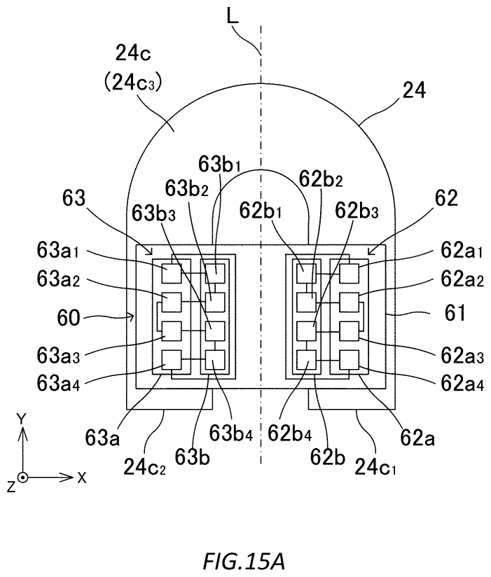

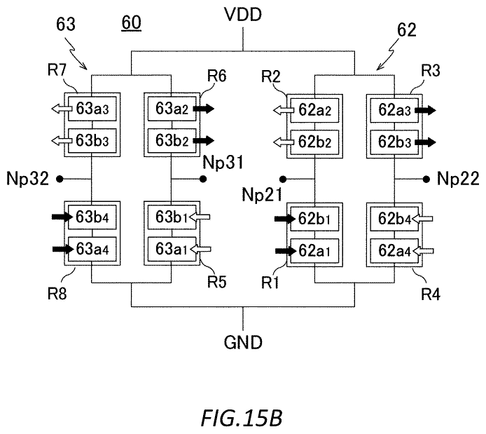

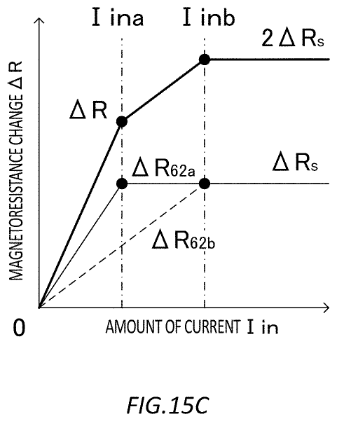

FIG. 15A illustrates an example of arrangement and a substrate layout of a magnetic sensor 60 according to a modification constituting such a magnetic sensor module. The magnetic sensor 60 is a sensor which detects the magnetic field generated around the bus bar 24 by the current to be measured applied to the bus bar 24. The magnetic sensor 60 is configured to detect, as an example, a magnetic field (an example of the horizontal magnetic field) in the X axis direction generated on the upper surface of the bus bar 24, and includes the substrate 61, a plurality of TMR elements 51, and a plurality of electrode pads (not illustrated). Note that the bus bar 24 has, as an example, a U shape or a substantially U shape (or may be C-shaped, π-shaped, or V-shaped).

The substrate 61 is a plate-shaped member which supports two magnetoelectric conversion units 62 and 63, and is installed on the bus bar 24 so as to be bridged between two arms 24c₁ and 24c₂ in the present example. The magnetoelectric conversion units 62 and 63 are an example of the magnetic sensor module, and are arranged by the substrate 61 so as to at least partially overlap the bus bar 24 when viewed from the Z axis direction. The substrate 61 is formed by using, for example, silicon (Si), and on one surface thereof, the magnetoelectric conversion units 62 and 63 are arranged to be separated in a direction (that is, the X axis direction) intersecting an energization direction of the bus bar 24.

The magnetoelectric conversion units 62 and 63 include a plurality of blocks (an example of a sub-magnetic sensor module) arrayed in the X axis direction on one surface of the substrate 61. In the present example, the plurality of blocks includes, relative to each other, first blocks 62a and 63a respectively located at centers of the arms 24c₁ and 24c₂ of the bus bar 24 or in vicinities thereof (that is, at locations where the magnetic field intensity is relatively high) and second blocks 62b and 63b respectively located remotely from the arms 24c₁ and 24c₂ (that is, at locations where the magnetic field intensity is relatively small, and at the end portions of the arms 24c₁ and 24c₂ in the present example). The first blocks 62a and 63a and the second blocks 62b and 63b are each arranged symmetrically with respect to a reference line L on the two arms 24c₁ and 24c₂ or on the end portions of respective arms. Note that the plurality of blocks is not limited to two and may include three or more blocks.

The first blocks 62a and 63a and the second blocks 62b and 63b includes one or more (four in the present example) sub-blocks 62a₁ to 62a₄, 62b₁ to 62b₄, 63a₁ to 63a₄, and 63b₁ to 63b₄, respectively. Furthermore, on one surface of the substrate 61, a plurality of wirings for electrically connecting the plurality of blocks 62a, 62b, 63a, and 63b or the plurality of sub-blocks 62a₁ to 62a₄, 62b₁ to 62b₄, 63a₁ to 63a₄, and 63b₁ to 63b₄ therein are laid.

The plurality of TMR elements 51 are elements resistance values of which fluctuate due to application of a magnetic field, and are disposed on one side and another side in the X axis direction on the substrate 61 to form the two magnetoelectric conversion units 62 and 63, respectively. The magnetoelectric conversion unit 62 is formed by configuring a part (that is, the TMR element 51 disposed on a right side in FIG. 15A) of the plurality of TMR elements 51 into a Wheatstone bridge shape (or a half bridge shape). Here, a further part of the part of the TMR elements 51 is disposed in the first block 62a, and another part is disposed in the second block 62b. The magnetoelectric conversion unit 63 is formed by configuring another part (that is, the TMR element 51 disposed on a left side in FIG. 15A) of the plurality of TMR elements 51 into a Wheatstone bridge shape (or a half bridge shape). Here, a further part of the another part of the TMR elements 51 is disposed in the first block 63a, and another part is disposed in the second block 63b.

FIG. 15B illustrates a circuit configuration of the full-bridge type magnetic sensor 60 (two magnetoelectric conversion units 62 and 63) and a magnetic field detection direction (also referred to as a magnetic sensing direction) of (the TMR element 51 included in each of) the resistive arms R1 to R8. The two magnetoelectric conversion units 62 and 63 are connected in parallel between the drive terminal VDD and the ground terminal GND in the magnetic sensor 60. As described above, the first blocks 62a and 63a and the second blocks 62b and 63b arranged on the substrate 61 include the four sub-blocks 62a₁ to 62a₄, 62b₁ to 62b₄, 63a₁ to 63a₄, and 63b₁ to 63b₄, respectively.

In the magnetoelectric conversion unit 62 (similarly also in the magnetoelectric conversion unit 63), inside the first sub-blocks 62a₁ and 62b₁ (63a₁ and 63b₁) respectively included in the first block 62a (63a) and the second block 62b (63b), the TMR elements 51 having magnetic sensing directions which are the same as each other as indicated by black arrows (white arrows) are disposed. The TMR element 51 within the first sub-block 62a₁ (63a₁) of the first block 62a (63a) and the TMR element 51 within the first sub-block 62b₁ (63b₁) of the second block 62b (63b) are connected in series to form the resistive arm R1 (R5).

Within the second sub-blocks 62a₂ and 62b₂ (63a₂ and 63b₂) respectively included in the first block 62a (63a) and the second block 62b (63b), the TMR elements 51 having magnetic sensing directions which are the same as each other as indicated by white arrows (black arrows) and are opposite to those of the TMR elements 51 within the first sub-blocks 62a₁ and 62b₁ (63a₁ and 63b₁) are disposed. The TMR element 51 within the second sub-block 62a₂ (63a₂) of the first block 62a (63a) and the TMR element 51 within the second sub-block 62b₂ (63b₂) of the second block 62b (63b) are connected in series to form the resistive arm R2 (R6).

Within the third sub-blocks 62a₃ and 62b₃ (63a₃ and 63b₃) respectively included in the first block 62a (63a) and the second block 62b (63b), the TMR elements 51 having magnetic sensing directions which are the same as each other as indicated by black arrows (white arrows) and are the same as those of the TMR elements 51 within the first sub-blocks 62a₁ and 62b₁ (63a₁ and 63b₁) are disposed. The TMR element 51 within the third sub-block 62a₃ (63a₃) of the first block 62a (63a) and the TMR element 51 within the third sub-block 62b₃ (63b₃) of the second block 62b (63b) are connected in series to form the resistive arm R3 (R7).

Within the fourth sub-blocks 62a₄ and 62b₄ (63a₄ and 63b₄) respectively included in the first block 62a (63a) and the second block 62b (63b), the TMR elements 51 having magnetic sensing directions which are the same as each other as indicated by white arrows (black arrows) and are opposite to those of the TMR elements 51 within the first sub-blocks 62a₁ and 62b₁ (63a₁ and 63b₁), that is, magnetic sensing directions which are the same as those of the TMR elements 51 within the second sub-blocks 62a₂ and 62b₂ (63a₂ and 63b₂) are disposed. The TMR element 51 within the fourth sub-block 62a₄ (63a₄) of the first block 62a (63a) and the TMR element 51 within the fourth sub-block 62b₄ (63b₄) of the second block 62b (63b) are connected in series to form the resistive arm R4 (R8).

The resistive arms R1 and R2 (R5 and R6) are connected in series with each other to form an output terminal Np21 (Np31) therebetween, the resistive arms R3 and R4 (R7 and R8) are connected in series with each other to form an output terminal Np22 (Np32) therebetween and are connected in parallel with the resistive arms R1 and R2 (R5 and R6), and the resistive arms R1 to R4 (R5 to R8) configures a Wheatstone bridge circuit.

Note that in the current sensor 110 according to the present embodiment, the magnetic sensing directions of the resistive arms R1 to R4 (R5 to R8) are uniaxial directions (the X axis direction in FIG. 1A) parallel to the upper surface of the bus bar 24. The magnetic sensing directions of the TMR elements 51 respectively forming the resistive arms R1 and R3 (R6 and R8) are the same as each other (indicated by black arrows in FIG. 15B), and in the present example, are set to a +X direction (or a −X direction) in FIG. 1A. The magnetic sensing directions of the TMR elements 51 respectively forming the resistive arms R2 and R4 (R5 and R7) are the same as each other (indicated by white arrows in FIG. 15B), and in the present example, are set to the −X direction (or +X direction) in FIG. 1A. The magnetic field detection directions of the resistive arms R1 and R3 (R6 and R8) are opposite to the magnetic sensing directions of the resistive arms R2 and R4 (R5 and R7).

At least a part of the magnetoelectric conversion unit 62 (63) is arranged on the arm 24c₁ (24c₂) of the bus bar 24. When the current to be measured flows through the bus bar 24 and a magnetic field is generated around the bus bar 24, the magnetic field in the X axis direction is applied to the TMR elements 51 included in the resistive arms R1 to R4 (R5 to R8) of the magnetoelectric conversion units 62 (63) arranged on the arm 24c₁ (24c₂) of the bus bar 24, and each resistance value (also referred to as a magnetoresistance) thereof fluctuates. For example, the resistance values of the resistive arms R1 and R3 (R5 and R7) increase (or decrease), and the resistance values of the resistive arms R2 and R4 (R6 and R8) decrease (or increase), thereby breaking a resistance balance of the resistive arms R1 to R4 (R5 to R8). Here, the magnetic field intensity can be detected by inputting a drive voltage to the drive terminal VDD with respect to the ground terminal GND and detecting a differential voltage output from between the output terminals Np21 and Np22 (Np31 and Np32). As a result, the horizontal magnetic field generated on the upper surface of the arm 24c₁ (24c₂) can be detected.

When the current to be measured flows through the bus bar 24 and the magnetic field Bx parallel to the X axis direction is generated above the bus bar 24 (arms 24c₁ and 24c₂), the TMR element 51 included in each of the magnetoelectric conversion units 62 and 63 linearly fluctuates the magnetoresistance according to the intensity of the applied magnetic field Bx, and is magnetically saturated (that is, the magnetoresistance becomes constant) when the intensity of the magnetic field Bx reaches a detection limit. Here, when each of the plurality of TMR elements 51 is similarly formed, they exhibit similar magnetic-sensitive characteristics. However, the intensity of the magnetic field Bx increases or decreases according to a relative position with respect to the bus bar 24 (arms 24c₁ and 24c₂), for example, exhibits a maximum at a center or approximately the center of each of the arms 24c₁ and 24c₂, and attenuates in a region between the arms 24c₁ and 24c₂ or in an outer region thereof. Therefore, a multiple linear sensor having a plurality of linearities with different sensitivities can be implemented by arranging the plurality of TMR elements 51 constituting the magnetoelectric conversion units 62 and 63 at different locations with respect to the bus bar 24 (arms 24c₁ and 24c₂).

FIG. 15C illustrates the magnetoresistance change ΔR of the TMR elements 51 within the first block 62a and the second block 62b and the entire sensor (magnetoelectric conversion unit 62) with respect to an amount of current Iin of the bus bar 24. Note that since an output voltage Vout of the magnetic sensor 60 (magnetoelectric conversion units 62 and 63) is proportional to the magnetoresistance change ΔR, the linearity of the output voltage Vout with respect to the amount of current Iin is equal to the linearity of the magnetoresistance change ΔR. In this regard, the linearity of the magnetoresistance change ΔR will be referred to unless otherwise specified. Since the first block 62a is located at the center of the arm 24c₁ on the substrate 61 or in a vicinity thereof, the TMR element 51 disposed inside the first block 62a increases a magnetoresistance ΔR₆₂ₐ with strong sensitivity to the amount of current Iin by applying the magnetic field Bx having almost the maximum intensity, and is magnetically saturated (ΔRₛ) at a small amount of current Iina or more. Note that the sensitivity varies depending on the position of the first block 62a in the X axis direction. On the other hand, since the second block 62b is located remotely from the arm 24c₁ (at the end portions of the two arms 24c₁ and 24c₂ in the present example), the TMR element 51 disposed inside the second block 62b increases a magnetoresistance ΔR_{62b} with weak sensitivity to the amount of current Iin by applying the relatively weak magnetic field Bx, and is magnetically saturated (ΔRₛ) at a relatively large amount of current Iinb or more. Note that the sensitivity varies depending on the position of the second block 62b in the X axis direction.

By connecting the TMR elements 51 within the first block 62a (sub-block 62a₁ to 62a₄) and the TMR elements 51 within the second block 62b (sub-block 62b₁ to 62b₄) in series to form the resistive arms R1 to R4, the magnetoresistance change ΔR of each of the resistive arms R1 to R4 exhibits double linearity in which, with respect to the current to be measured Iin, the magnetoresistance change ΔR increases with strong sensitivity (that is, a large slope) in a range of the amount of current Iina or less, increases with weak sensitivity (small slope) in a range of the amounts of current Iina to Iinb, and becomes magnetically saturated in a range of the amount of current Iinb or more. Here, the TMR elements 51 within the first block 62a and the TMR elements 51 within the second block 62b may have a same structure and can be formed by a same process, and the magnetic sensor 60 can be configured with a small chip area since an amplifier for realizing a plurality of linearities is not required.

Note that since the structures and processes of the plurality of TMR elements 51 are the same, the magnetoresistance change ΔR of the TMR elements 51 within the first block 63a and the second block 63b and the magnetoelectric conversion unit 63 with respect to the energization amount of the bus bar 24 is similar to the magnetoresistance change ΔR of the TMR elements 51 within the first block 62a and the second block 62b and the magnetoelectric conversion units 62.

Note that two magnetoelectric conversion units 62 and 63 can be arranged on one side and another side in the X axis direction symmetrically with respect to the reference line L (see FIG. 15A), respectively. As a result, a disturbance magnetic field can be canceled. In addition, the drive terminals VDD, the ground terminals GND, and the output terminals Np21, Np22, Np31, and Np32 of the two magnetoelectric conversion units 62 and 63 may be connected to a plurality of electrode pads on the substrate 61.

The plurality of electrode pads are disposed on the substrate 61 and are connected by wiring to the drive terminals VDD and the ground terminals GND of the two magnetoelectric conversion units 62 and 63, the two output terminals Np21 and Np22 of the magnetoelectric conversion unit 62, and the two output terminals Np31 and Np32 of the magnetoelectric conversion unit 63, and are pads for inputting a drive voltage to the drive terminal VDD from the outside and outputting a differential voltage from the output terminals Np21, Np22, Np31, and Np32 to the outside. The electrode pads are molded on the substrate 61 by using a conductive metal such as gold, copper, or aluminum, and are arranged side by side in the X axis direction on a +Y side (a left side in FIG. 1A), for example.

The magnetic sensor 60 is arranged on the curved portion 24c of the bus bar 24. Accordingly, the two magnetoelectric conversion units 62 and 63 are arranged on the two arms 24c₁ and 24c₂ of the curved portion 24c, respectively, and the plurality of electrode pads on the substrate 61 connected to the drive terminals VDD, the ground terminals GND, and the output terminals Np21, Np22, Np31, and Np32 of the two magnetoelectric conversion units 62 and 63 are connected to the device terminal 17 by wire bonding. Accordingly, it is possible to apply a drive voltage to the two magnetoelectric conversion units 62 and 63 via the device terminal 17 and to output each differential voltage thereof.

Note that in the magnetic sensor 60, centroids of the plurality of magnetic sensor modules (sub-blocks) constituting the resistive arms R1 and R5, centroids of the plurality of magnetic sensor modules (sub-blocks) constituting the resistive arms R2 and R6, centroids of the plurality of magnetic sensor modules (sub-blocks) constituting the resistive arms R3 and R7, and centroids of the plurality of magnetic sensor modules (sub-blocks) constituting the resistive arms R4 and R8 may be aligned in position in the X axis direction and/or the Y axis direction. Accordingly, the magnetic field intensity distribution on the bus bar 24 applied to the TMR element forming each resistive arm is averaged, so that highly accurate measurement can be performed.

Here, a method of manufacturing the current sensor 110 will be described.

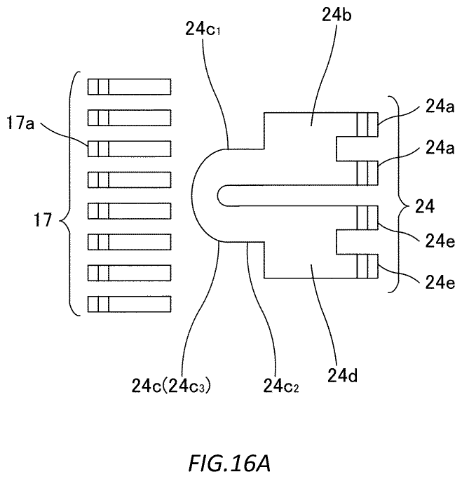

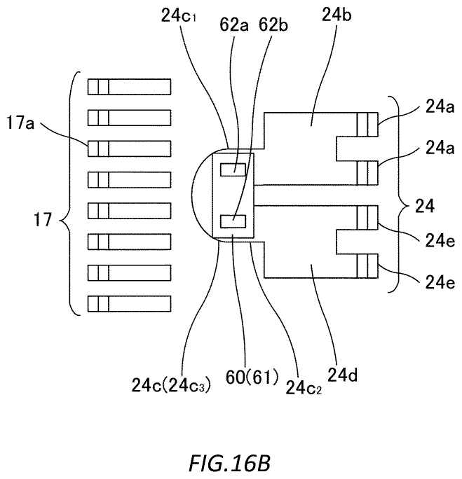

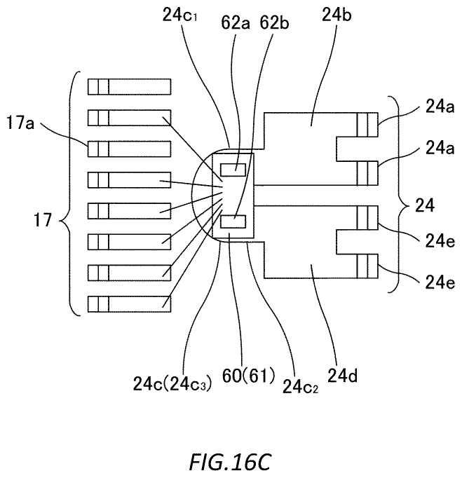

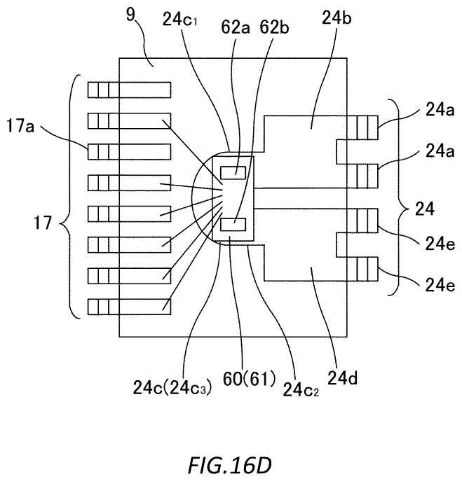

As illustrated in FIG. 16A, first, one metal plate is pressed to mold a pattern of a plurality of device terminals 17 and the bus bar 24. This pattern includes the plurality of device terminals 17 and the bus bar 24 having their terminal portions coupled to an inside of a rectangular frame-shaped frame (not illustrated).

Next, level difference processing is performed on the pattern to provide a level difference to the plurality of device terminals 17 and the bus bar 24. Accordingly, an inner part of the pattern is raised with respect to the frame and those terminal portions coupled to the frame.

As illustrated in FIG. 16B, next, the magnetic sensor 60 is installed. Here, the two magnetoelectric conversion units 62a and 62b are arranged on the arms 24c₁ and 24c₂ of the bus bar 24, respectively.

As illustrated in FIG. 16C, next, the magnetic sensor 60 and the plurality of device terminals 17 are connected by wire bonding.

As illustrated in FIG. 16D, next, the pattern is molded, leaving the frame and the terminal portions of the plurality of device terminals 17 and the bus bar 24 coupled to the frame. Accordingly, the package 9 is molded, and the magnetic sensor 60 and the inner part of the pattern are sealed therein.

Finally, the frame exposed from the package 9 is cut from the pattern. As a result, the plurality of device terminals 17 and the bus bar 24 are separated from each other, and the current sensor 110 is completed.

Note that the current sensor 110 may further include a signal processing device which processes an output signal of the magnetic sensor 60 and calculates an amount of the current to be measured applied to the bus bar 24 and a base which supports the signal processing device (both not illustrated). The signal processing device may incorporate a memory, a sensitivity correction circuit, an offset correction circuit which corrects an offset of an output, an amplifier circuit which amplifies an output signal from the magnetic sensor 60, and a temperature correction circuit which corrects an output according to temperature. The signal processing device may be supported on the base and connected to the magnetic sensor 60 and the plurality of device terminals 17 by wire bonding. Alternatively, the signal processing device may be incorporated into the substrate 61 having the magnetic sensor 60, with the electrode pad serving as an input/output terminal of the signal processing device, and may be connected to the plurality of device terminals 17 by wire bonding. Accordingly, the signal processing device outputs, via the plurality of device terminals 17, a calculation result of the amount of the current to be measured supplied to the bus bar 24.

While the embodiments of the present invention have been described, the technical scope of the invention is not limited to the above-described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A tunnel magnetoresistance element comprising
a fixed layer, an insulating layer, and a free layer which are sequentially stacked in a uniaxial direction, wherein
the free layer has a column shape extending in the uniaxial direction and spreading in a planar direction intersecting the uniaxial direction, and with a height t of the free layer in the uniaxial direction and an effective size d of the free layer with respect to spread in the planar direction, an aspect ratio (t/d) given by using the height t and the effective size d is 1 or more, the height t is 20 nm or more, and the effective size d is 2.57×10⁻² (A)/Ms or less, with a saturation magnetization Ms (A/nm) of the free layer.

2. The tunnel magnetoresistance element according to claim 1, wherein the saturation magnetization is 0.75×10⁻⁹/μ₀ (A/nm) or less, and the effective size is 20 nm or more.

3. The tunnel magnetoresistance element according to claim 1, wherein the effective size d is 20 nm or more, and the height t is 200 nm or less.

4. The tunnel magnetoresistance element according to claim 1, wherein ½ of the effective size d is equal to or less than 4 times an exchange length within the free layer.

5. The tunnel magnetoresistance element according to claim 1, wherein the free layer has a cylindrical shape.

6. The tunnel magnetoresistance element according to claim 1, wherein the free layer has a polygonal column shape.

7. The tunnel magnetoresistance element according to claim 1, wherein the free layer includes NiₓFe₁₋ₓ (x=0.25 to 0.30) forming a body-centered cubic lattice.

8. The tunnel magnetoresistance element according to claim 1, further comprising
a cap layer which is stacked on the free layer, wherein
the free layer contains at least cobalt (Co) and/or iron (Fe), the insulating layer contains at least magnesium oxide (MgO), and the cap layer contains at least tantalum (Ta) or ruthenium (Ru).

9. The tunnel magnetoresistance element according to claim 1, wherein the free layer contains cobalt (Co) and/or iron (Fe), and further contains at least one type of paramagnetic transition metal elements.

10. The tunnel magnetoresistance element according to claim 9, wherein the paramagnetic transition metal elements are any of Ti, Cr, Mn, Cu, Zn, Mo, Ru, Rh, Pd, Ag, Ta, W, Pt, Au, or Ti.

11. A tunnel magnetoresistance element comprising
a fixed layer, an insulating layer, and a free layer which are sequentially stacked in a uniaxial direction, wherein
the free layer has a column shape extending in the uniaxial direction and spreading in a planar direction intersecting the uniaxial direction, and
a magnetic moment within the free layer is oriented in the uniaxial direction or oriented in a direction inclined circumferentially about a central axis of the column shape with respect to the uniaxial direction.

12. The tunnel magnetoresistance element according to claim 1, wherein a magnetic moment within the fixed layer is oriented in a planar direction intersecting with the uniaxial direction, and the tunnel magnetoresistance element is for use in a magnetic sensor.

13. A magnetic sensor module, wherein at least two tunnel magnetoresistance elements, each identical to the tunnel magnetoresistance element according to claim 12, are arranged on a same plane and connected in parallel between two electrodes.

14. The magnetic sensor module according to claim 13, wherein an area filling rate of the tunnel magnetoresistance element on the same plane is 11 to 55%.

15. The magnetic sensor module according to claim 13, wherein a distance between two tunnel magnetoresistance elements adjacent to each other on the same plane is 4 to 25 nm.

16. The magnetic sensor module according to claim 13, wherein a plurality of tunnel magnetoresistance elements, each identical to the tunnel magnetoresistance element, have one or more types of polygonal shapes that allow for close-packing.

17. The magnetic sensor module according to claim 13, wherein a plurality of tunnel magnetoresistance elements, each identical to the tunnel magnetoresistance element, are periodically arrayed in a third direction on the same plane and a fourth direction intersecting the third direction, and an array pitch of the tunnel magnetoresistance elements in the third direction is larger than an array pitch in the fourth direction.

18. A current sensor comprising the magnetic sensor module according to claim 17 arranged on a U-shaped or substantially U-shaped bus bar, wherein the third direction is parallel to a direction of a current flowing through the bus bar.

19. A magnetic sensor module, wherein at least two tunnel magnetoresistance elements, each identical to the tunnel magnetoresistance element according to claim 12, are arranged on a same plane and connected between two electrodes.

20. A current sensor comprising
the magnetic sensor module according to claim 19 arranged on a U-shaped or substantially U-shaped bus bar, wherein
at least a part of the magnetic sensor module overlaps the bus bar when viewed from the uniaxial direction.

21. The current sensor according to claim 20, comprising a substrate which is installed on the bus bar and in which a plurality of magnetic sensor modules, each identical to the magnetic sensor module, including a first magnetic sensor module and a second magnetic sensor module respectively located near and remote from a center of the bus bar relative to each other are arranged on one surface, wherein
each of the first magnetic sensor module and the second magnetic sensor module includes a first sub magnetic sensor module in which magnetoresistance elements having magnetic sensing directions which are the same as each other are disposed, and a magnetoresistance element within the first sub magnetic sensor module of the first magnetic sensor module and a magnetoresistance element within the first sub magnetic sensor module of the second magnetic sensor module are connected in series to form a first resistive arm.

22. The current sensor according to claim 20, comprising
a first resistive arm, a second resistive arm, a third resistive arm, and a fourth resistive arm which include a plurality of magnetic sensor modules, each identical to the magnetic sensor module, and form a bridge circuit, wherein
the plurality of magnetic sensor modules are separated from each other, and
centroids of a plurality of magnetic sensor modules constituting the first resistive arm, centroids of a plurality of magnetic sensor modules constituting the second resistive arm, centroids of a plurality of magnetic sensor modules constituting the third resistive arm, and centroids of a plurality of magnetic sensor modules constituting the fourth resistive arm coincide with each other.
